(19) United States
(12) Patent Application Publication
(10) Pub. No.: US 2026/0255570 A1
(43) Pub. Date: Aug. 27, 2026

(54) SEMICONDUCTOR MEMORY DEVICE

(71) Applicant: Kioxia Corporation, Tokyo (JP)

(72) Inventor: Takafumi MASUDA, Yokkaichi Mie (JP)

(73) Assignee: Kioxia Corporation, Tokyo (JP)

(21) Appl. No.: 19/327,475

(22) Filed: Sep. 12, 2025

(30) Foreign Application Priority Data
Feb. 27, 2025 (JP) 2025-029678

(51) Int. Cl. H10B 12/00

(52) U.S. Cl. CPC H10B 12/00

(57) ABSTRACT

A semiconductor memory device includes first wirings, second wirings, a first insulating member and a second insulating member disposed therebetween, first semiconductor layers, first gate electrodes electrically connected to the first wirings and opposed to the first semiconductor layers, second semiconductor layers, second gate electrodes electrically connected to the second wirings and opposed to the second semiconductor layers, third semiconductor layers electrically connected to the second semiconductor layers, third gate electrodes electrically connected to the first semiconductor layers and opposed to the third semiconductor layers, and a via-wiring electrically connected to the third semiconductor layers. On a predetermined cross-sectional surface, an end portion of the via-wiring on one side is disposed between positions corresponding to side surfaces of the first insulating member and the second insulating member, and an end portion on the other side is not disposed therebetween.

### CROSS-REFERENCE TO RELATED APPLICATIONS

This application is based upon and claims the benefit of Japanese Patent Application No. 2025-029678, filed on Feb. 27, 2025, the entire contents of which are incorporated herein by reference.

### BACKGROUND

### Field

Embodiments described herein relate generally to a semiconductor memory device.

### Description of the Related Art

In accordance with an increasing high integration of a semiconductor memory device, an examination for converting the semiconductor memory device into a three-dimensional form has been in progress.

### BRIEF DESCRIPTION OF THE DRAWINGS

FIG. 1 is a schematic circuit diagram illustrating a configuration of a part of a semiconductor memory device according to a first embodiment;

FIG. 2 is a schematic perspective view illustrating a configuration of a part of the semiconductor memory device;

FIG. 3 is a schematic XY cross-sectional view illustrating a configuration of a part of the semiconductor memory device;

FIG. 4 is a schematic cross-sectional view illustrating a configuration of a part of the semiconductor memory device;

FIG. 5 is a schematic cross-sectional view for describing a manufacturing method of the semiconductor memory device;

FIG. 6 is a schematic cross-sectional view for describing the manufacturing method;

FIG. 7 is a schematic cross-sectional view for describing the manufacturing method;

FIG. 8 is a schematic cross-sectional view for describing the manufacturing method;

FIG. 9 is a schematic cross-sectional view for describing the manufacturing method;

FIG. 10 is a schematic cross-sectional view for describing the manufacturing method;

FIG. 11 is a schematic cross-sectional view for describing the manufacturing method;

FIG. 12 is a schematic cross-sectional view for describing the manufacturing method;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing the manufacturing method;

FIG. 29 is a schematic cross-sectional view for describing the manufacturing method;

FIG. 30 is a schematic cross-sectional view for describing the manufacturing method;

FIG. 31 is a schematic cross-sectional view for describing the manufacturing method;

FIG. 32 is a schematic cross-sectional view for describing the manufacturing method;

FIG. 33 is a schematic cross-sectional view for describing the manufacturing method;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view for describing the manufacturing method;

FIG. 38 is a schematic cross-sectional view for describing the manufacturing method;

FIG. 39 is a schematic cross-sectional view for describing the manufacturing method;

FIG. 40 is a schematic cross-sectional view for describing the manufacturing method;

FIG. 41 is a schematic cross-sectional view for describing the manufacturing method;

FIG. 42 is a schematic cross-sectional view for describing the manufacturing method;

FIG. 43 is a schematic cross-sectional view for describing the manufacturing method;

FIG. 44 is a schematic cross-sectional view for describing the manufacturing method;

FIG. 45 is a schematic cross-sectional view for describing the manufacturing method;

FIG. 46 is a schematic cross-sectional view for describing the manufacturing method;

FIG. 47 is a schematic cross-sectional view for describing the manufacturing method;

FIG. 48 is a schematic cross-sectional view for describing the manufacturing method;

FIG. 49 is a schematic cross-sectional view for describing the manufacturing method;

FIG. 50 is a schematic cross-sectional view for describing the manufacturing method;

FIG. 51 is a schematic cross-sectional view for describing the manufacturing method;

FIG. 52 is a schematic cross-sectional view for describing the manufacturing method;

FIG. 53 is a schematic cross-sectional view for describing the manufacturing method;

FIG. 54 is a schematic cross-sectional view for describing the manufacturing method;

FIG. 55 is a schematic cross-sectional view for describing the manufacturing method;

FIG. 56 is a schematic cross-sectional view for describing the manufacturing method;

FIG. 57 is a schematic cross-sectional view for describing the manufacturing method;

FIG. 58 is a schematic cross-sectional view for describing the manufacturing method;

FIG. 59 is a schematic cross-sectional view for describing the manufacturing method;

FIG. 60 is a schematic cross-sectional view for describing the manufacturing method;

FIG. 61 is a schematic cross-sectional view for describing the manufacturing method;

FIG. 62 is a schematic cross-sectional view for describing the manufacturing method;

FIG. 63 is a schematic cross-sectional view for describing the manufacturing method;

FIG. 64 is a schematic cross-sectional view for describing the manufacturing method;

FIG. 65 is a schematic cross-sectional view for describing the manufacturing method;

FIG. 66 is a schematic cross-sectional view for describing the manufacturing method;

FIG. 67 is a schematic cross-sectional view for describing the manufacturing method;

FIG. 68 is a schematic cross-sectional view for describing the manufacturing method;

FIG. 69 is a schematic cross-sectional view for describing the manufacturing method;

FIG. 70 is a schematic cross-sectional view for describing the manufacturing method;

FIG. 71 is a schematic cross-sectional view for describing the manufacturing method;

FIG. 72 is a schematic cross-sectional view for describing the manufacturing method;

FIG. 73 is a schematic cross-sectional view for describing the manufacturing method;

FIG. 74 is a schematic cross-sectional view for describing the manufacturing method;

FIG. 75 is a schematic cross-sectional view for describing the manufacturing method;

FIG. 76 is a schematic cross-sectional view for describing the manufacturing method;

FIG. 77 is a schematic cross-sectional view for describing the manufacturing method;

FIG. 78 is a schematic cross-sectional view for describing the manufacturing method;

FIG. 79 is a schematic cross-sectional view for describing the manufacturing method;

FIG. 80 is a schematic cross-sectional view for describing the manufacturing method;

FIG. 81 is a schematic cross-sectional view for describing the manufacturing method;

FIG. 82 is a schematic cross-sectional view for describing the manufacturing method;

FIG. 83 is a schematic cross-sectional view for describing the manufacturing method;

FIG. 84 is a schematic cross-sectional view for describing the manufacturing method;

FIG. 85 is a schematic cross-sectional view for describing the manufacturing method;

FIG. 86 is a schematic cross-sectional view for describing the manufacturing method;

FIG. 87 is a schematic cross-sectional view for describing the manufacturing method;

FIG. 88 is a schematic cross-sectional view for describing the manufacturing method;

FIG. 89 is a schematic cross-sectional view for describing the manufacturing method;

FIG. 90 is a schematic cross-sectional view for describing the manufacturing method;

FIG. 91 is a schematic cross-sectional view for describing the manufacturing method;

FIG. 92 is a schematic cross-sectional view for describing the manufacturing method;

FIG. 93 is a schematic cross-sectional view for describing the manufacturing method;

FIG. 94 is a schematic cross-sectional view for describing the manufacturing method;

FIG. 95 is a schematic cross-sectional view for describing the manufacturing method;

FIG. 96 is a schematic cross-sectional view for describing the manufacturing method;

FIG. 97 is a schematic cross-sectional view for describing the manufacturing method;

FIG. 98 is a schematic cross-sectional view for describing the manufacturing method;

FIG. 99 is a schematic XY cross-sectional view illustrating a configuration of a part of a semiconductor memory device according to a second embodiment;

FIG. 100 is a schematic XY cross-sectional view illustrating a configuration of a part of a semiconductor memory device according to a third embodiment;

FIG. 101 is a schematic XY cross-sectional view illustrating a configuration of a part of a semiconductor memory device according to a fourth embodiment;

FIG. 102 is a schematic cross-sectional view illustrating a configuration of a part of the semiconductor memory device;

FIG. 103 is a schematic XY cross-sectional view illustrating a configuration of a part of a semiconductor memory device according to a fifth embodiment;

FIG. 104 is a schematic cross-sectional view illustrating a configuration of a part of the semiconductor memory device;

FIG. 105 is a schematic XY cross-sectional view illustrating a configuration of a part of a semiconductor memory device according to a sixth embodiment; and

FIG. 106 is a schematic cross-sectional view illustrating a configuration of a part of the semiconductor memory device.

### DETAILED DESCRIPTION

A semiconductor memory device according to one embodiment comprises: a plurality of first wirings arranged in a first direction and extending in a second direction intersecting with the first direction; a plurality of second wirings arranged in the first direction, extending in the second direction, and arranged with the plurality of first wirings in a third direction intersecting with the first direction and the second direction; and a first insulating member and a second insulating member disposed between the plurality of first wirings and the plurality of second wirings, arranged in the second direction, and extending in the first direction and the third direction.

Furthermore, the semiconductor memory device comprises: a plurality of first semiconductor layers disposed between the first insulating member and the second insulating member, arranged in the first direction, and extending in the third direction; a plurality of first gate electrodes arranged in the first direction, electrically connected to the respective plurality of first wirings, and opposed to the plurality of first semiconductor layers; and a first via-wiring extending in the first direction and electrically connected to the plurality of first semiconductor layers.

Furthermore, the semiconductor memory device comprises: a plurality of second semiconductor layers disposed between the first insulating member and the second insulating member, arranged in the first direction, and extending in the third direction; a plurality of second gate electrodes arranged in the first direction, electrically connected to the respective plurality of second wirings, and opposed to the plurality of second semiconductor layers; and a second via-wiring extending in the first direction and electrically connected to the plurality of second semiconductor layers.

Furthermore, the semiconductor memory device comprises: a plurality of third semiconductor layers disposed between the plurality of first semiconductor layers and the plurality of second semiconductor layers, arranged in the first direction, and extending in the third direction, in which the plurality of third semiconductor layers are electrically connected to the respective plurality of second semiconductor layers; a plurality of third gate electrodes arranged in the first direction, electrically connected to the respective plurality of first semiconductor layers, and opposed to the plurality of third semiconductor layers; and a third via-wiring extending in the first direction and electrically connected to the plurality of third semiconductor layers.

On a predetermined cross-sectional surface extending in the second direction and the third direction, an end portion of the third via-wiring on one side in the second direction is disposed between a first position in the second direction corresponding to a side surface of the first insulating member on a second insulating member side and a second position in the second direction corresponding to a side surface of the second insulating member on a first insulating member side, and an end portion of the third via-wiring on the other side in the second direction is not disposed between the first position and the second position.

Next, the semiconductor memory devices according to embodiments are described in detail with reference to the drawings. The following embodiments are only examples, and not described for the purpose of limiting the present invention. The following drawings are schematic, and for convenience of description, a part of a configuration or the like is sometimes omitted. Parts common in a plurality of embodiments are attached by same reference numerals and their descriptions may be omitted.

In this specification, when referring to a "semiconductor memory device", it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration "is electrically connected" to a second configuration, the first configuration may be directly connected to the second configuration, and the first configuration may be connected to the second configuration via a wiring, a semiconductor layer material, a transistor, or the like. For example, when three transistors are connected in series, even when the second transistor is in an OFF state, the first transistor is "electrically connected" to the third transistor.

In this specification, when it is referred that the first configuration "is electrically connected between" the second configuration and a third configuration, it may mean that the first configuration, the second configuration, and the third configuration are connected in series and the second configuration is electrically connected to the third configuration via the first configuration.

In this specification, when it is referred that a circuit or the like "electrically conducts" two wirings or the like, it may mean, for example, that this circuit or the like includes a transistor or the like, this transistor or the like is disposed in a current path between the two wirings, and this transistor or the like enters an ON state.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction intersecting with a predetermined plane may be referred to as a first direction, a direction along this predetermined plane may be referred to as a second direction, and a direction intersecting with this predetermined plane and intersecting with the second direction may be referred to as a third direction. These first direction, second direction, and third direction may each correspond to any of the Z-direction, the Y-direction, and the X-direction and need not correspond to these directions.

Expressions such as "above" and "below" in this specification are based on the substrate. For example, a direction away from the substrate along the Z-direction is referred to as above and a direction approaching the substrate along the Z-direction is referred to as below. A lower surface and a lower end of a certain configuration mean a surface and an end portion of this configuration at the substrate side. An upper surface and an upper end of a certain configuration mean a surface and an end portion of this configuration on a side opposite to the substrate. A surface intersecting with the X-direction or the Y-direction is referred to as a side surface or the like.

In this specification, a "center position" of a certain configuration may mean, for example, a position of the center of a circumscribed circle of this configuration, and may mean the centroid of this configuration on an image.

### First Embodiment

### Circuit Configuration

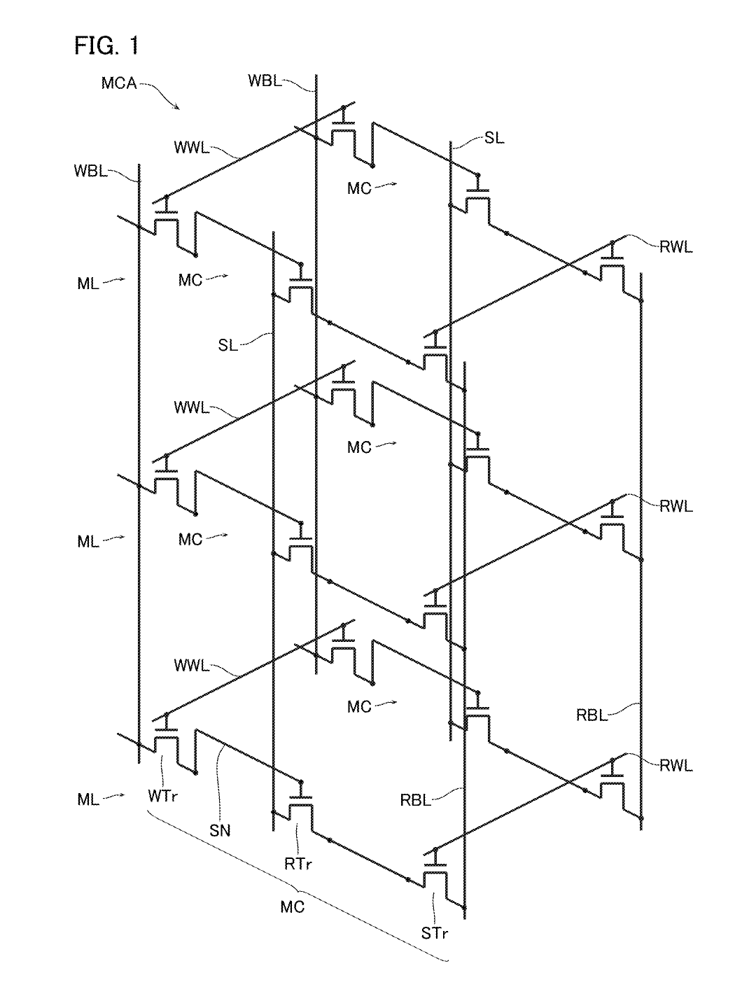

FIG. 1 is a schematic circuit diagram illustrating a configuration of a part of a semiconductor memory device according to a first embodiment. As illustrated in FIG. 1, the semiconductor memory device according to the embodiment includes a memory cell array MCA. The memory cell array MCA includes a plurality of memory layers ML, a plurality of write bit lines WBL connected to these plurality of memory layers ML, a plurality of read bit lines RBL connected to the plurality of memory layers ML, and a plurality of source lines SL connected to the plurality of memory layers ML.

Each of the memory layers ML includes a write word line WWL, a read word line RWL, and a plurality of memory cells MC connected to these write word line WWL and read word line RWL. Each of the memory cells MC includes a write transistor WTr, a storage node SN, a read transistor RTr, and a select transistor STr.

The write transistor WTr is, for example, a field-effect type NMOS transistor. The write transistor WTr has one electrode connected to the write bit line WBL. The write transistor WTr has the other electrode connected to the storage node SN. The one and the other electrodes of the write transistor WTr function as a source electrode or a drain electrode according to a voltage applied to the write transistor WTr. The write transistor WTr has a gate electrode connected to the write word line WWL.

The read transistor RTr is, for example, a field-effect type NMOS transistor. The read transistor RTr has one electrode connected to the source line SL. For example, a ground voltage Vss is applied to the source line SL. The read transistor RTr has the other electrode connected to the select transistor STr. The one and the other electrodes of the read transistor RTr function as a source electrode or a drain electrode according to a voltage applied to the read transistor RTr. The read transistor RTr has a gate electrode connected to the storage node SN.

The select transistor STr is, for example, a field-effect type NMOS transistor. The select transistor STr has one electrode connected to the read bit line RBL. The select transistor STr has the other electrode connected to the read transistor RTr. The one and the other electrodes of the select transistor STr function as a source electrode or a drain electrode according to a voltage applied to the select transistor STr. The select transistor STr has a gate electrode connected to the read word line RWL.

In a write operation, for example, a predetermined gate voltage is applied to a write word line WWL that is a target of the write operation, and the ground voltage Vss is applied to the other write word lines WWL among the plurality of write word lines WWL. The predetermined gate voltage is, for example, a voltage having a magnitude obtained by adding a threshold voltage of the write transistor WTr to a power supply voltage Vdd. Further, the power supply voltage Vdd or the ground voltage Vss is applied to a write bit line WBL that is the target of the write operation among the plurality of write bit lines WBL according to data to be written.

In the write operation, all the write bit lines WBL in the memory cell array MCA may be the target of the write operation, or a part (for example, one) of the write bit lines WBL may be the target of the write operation. In the latter case, the write bit lines WBL that are not the target of the write operation among the plurality of write bit lines WBL may be, for example, in a floating state.

In a read operation, for example, the power supply voltage Vdd is applied to a read word line RWL that is a target of the read operation, and the ground voltage Vss is applied to the other read word lines RWL among the plurality of read word lines RWL. Here, when the storage node SN of the memory cell MC as the target of the read operation (hereinafter referred to as a "selected memory cell MC" in some cases) has been charged with the power supply voltage Vdd, the read transistor RTr turns ON, causing a current to flow through the read bit line RBL or an electric charge in the read bit line RBL to be discharged. On the other hand, when the storage node SN of the selected memory cell MC has been discharged to the ground voltage Vss, the read transistor RTr turns OFF. Accordingly, a current does not flow through the read bit line RBL, or the electric charge in the read bit line RBL is not discharged.

In the read operation, all the read bit lines RBL in the memory cell array MCA may be the target of the read operation, or a part (for example, one) of the read bit lines RBL may be the target of the read operation. In the latter case, for example, the ground voltage Vss may be applied to the read bit lines RBL that are not the target of the read operation among the plurality of read bit lines RBL.

### Structure

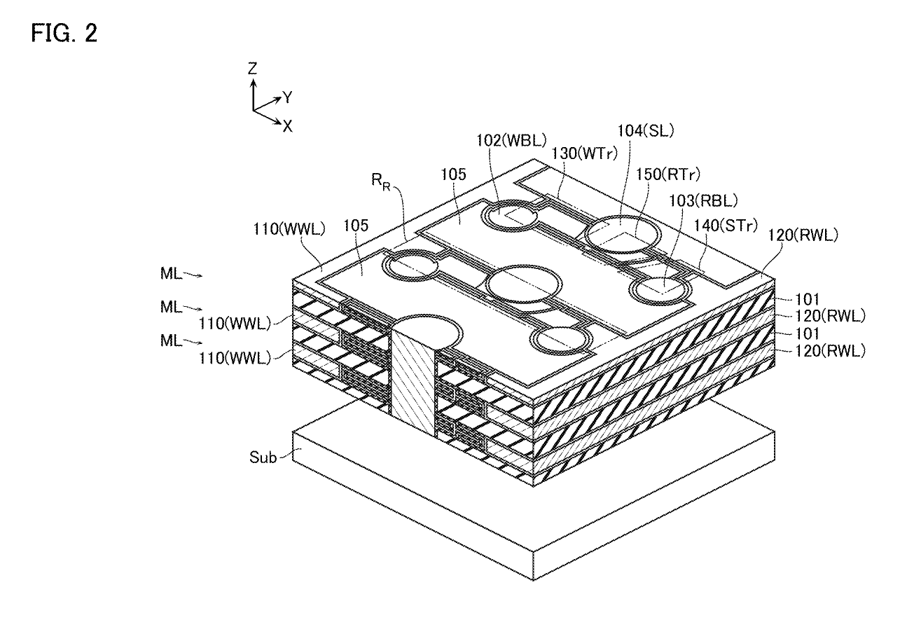

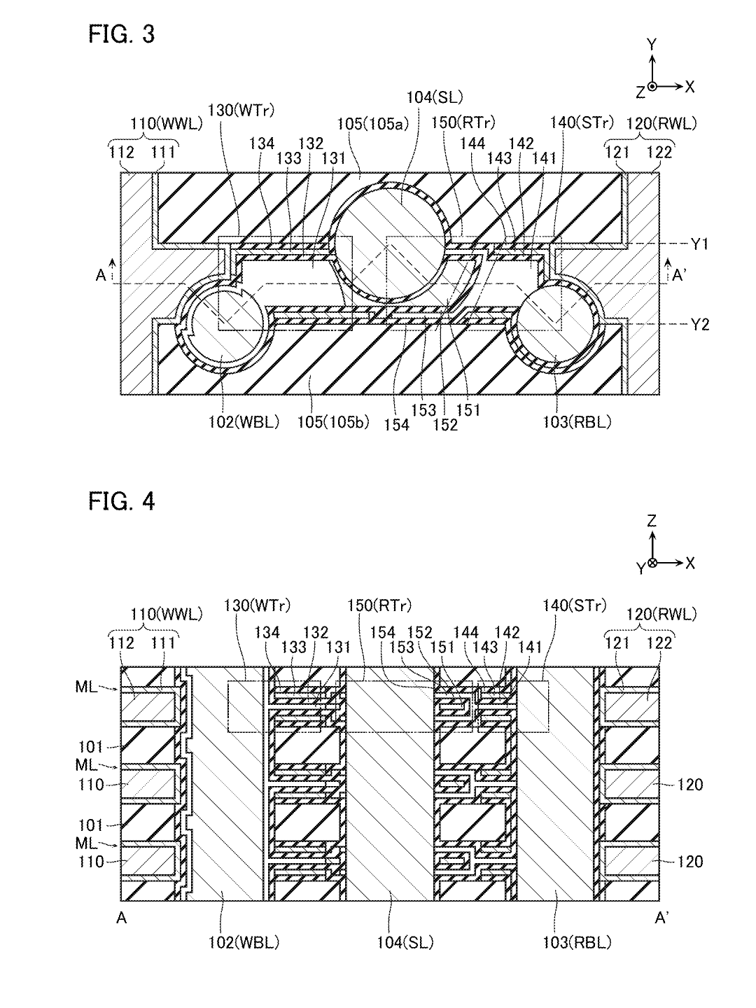

FIG. 2 is a schematic perspective view illustrating a configuration of a part of the semiconductor memory device according to the first embodiment. FIG. 3 is a schematic XY cross-sectional view illustrating a configuration of a part of the semiconductor memory device. FIG. 4 is a schematic cross-sectional view illustrating a configuration of a part of the semiconductor memory device, and illustrates a configuration of the structure illustrated in FIG. 3 taken along the line A-A' when viewed in the arrow direction.

FIG. 2 illustrates a part of a semiconductor substrate Sub and a part of the memory cell array MCA disposed above the semiconductor substrate Sub.

The semiconductor substrate Sub includes silicon (Si) or the like containing P-type impurities, such as boron (B). An insulating layer and an electrode layer (not illustrated) are disposed on an upper surface of the semiconductor substrate Sub. The upper surface of the semiconductor substrate Sub, and the insulating layer and the electrode layer (not illustrated) constitute a control circuit for controlling the semiconductor memory device. For example, in a region immediately below the memory cell array MCA, a sense amplifier circuit is disposed. The sense amplifier circuit is electrically connected to the read bit lines RBL. The sense amplifier circuit can read data stored in the selected memory cell MC by detecting a voltage or a current of the read bit line RBL in the read operation.

The memory cell array MCA includes a plurality of memory layers ML arranged in the Z-direction. In addition, insulating layers 101 of silicon oxide (SiO₂) or the like are disposed between the respective plurality of memory layers ML.

The memory cell array MCA includes via-wirings 102, 103, 104. The via-wiring 102 functions as the write bit line WBL. The via-wiring 103 functions as the read bit line RBL. The via-wiring 104 functions as the source line SL. The via-wirings 102, 103, 104 have different positions in the X-direction from one another, penetrate the plurality of memory layers ML, and extend in the Z-direction.

The via-wiring 102 includes, for example, a conductive oxide film containing a conductive oxide, a barrier conductive film of titanium nitride (TiN) or the like, and a conductive member of tungsten (W) or the like. The via-wiring 102 may contain ruthenium (Ru), iridium (Ir), or another metal instead of the conductive oxide film. In addition, the via-wiring 102 may contain only the conductive oxide, or may contain only ruthenium (Ru), iridium (Ir), or another metal.

In this specification, the "conductive oxide" contains, for example, indium tin oxide (ITO), indium zinc oxide (IZO), ruthenium oxide (RuO₂), iridium oxide (IrO₂), or another conductive material containing oxygen.

The via-wiring 103 includes, for example, a conductive oxide film containing a conductive oxide, a barrier conductive film of titanium nitride (TiN) or the like, and a conductive member of tungsten (W) or the like. The via-wiring 103 may contain ruthenium (Ru), iridium (Ir), or another metal instead of the conductive oxide film. In addition, the via-wiring 103 may contain only the conductive oxide, or may contain only ruthenium (Ru), iridium (Ir), or another metal.

The memory cell array MCA includes insulating members 105 of silicon oxide (SiO₂) or the like. The insulating members 105 penetrate the plurality of memory layers ML and extend in the Z-direction. The insulating members 105 are arranged in the Y-direction, extend in the X-direction, and electrically separate the plurality of memory cells MC arranged in the Y-direction.

The memory layer ML includes wirings 110, 120 arranged in the X-direction and extending in the Y-direction. In the examples of FIG. 2 and FIG. 3, a region between the wirings 110, 120 in the memory layer ML is partitioned into a plurality of approximately rectangular regions R_{R} (FIG. 2) by the plurality of insulating members 105 arranged in the Y-direction. The memory layer ML also includes transistor structures 130 disposed in regions at the wiring 110 side in the regions R_{R}, transistor structures 140 disposed in regions at the wiring 120 side in the regions R_{R}, and transistor structures 150 disposed in regions between the transistor structures 130, 140 in the regions R_{R}.

In addition, in the examples of FIG. 2 and FIG. 3, a part of the via-wiring 102, a part of the via-wiring 103, and a part of the via-wiring 104 protrude from the region R_{R} and dig into the insulating members 105.

Further, in the examples of FIG. 2 and FIG. 3, the via-wiring 104 protrudes from the region R_{R} to a positive side in the Y-direction, and the via-wirings 102, 103 protrude from the region R_{R} to a negative side in the Y-direction. That is, the via-wiring 104 has a part disposed in the region R_{R} and a part disposed on the positive side in the Y-direction with respect to the region R_{R}. On the other hand, the via-wirings 102, 103 have parts disposed in the region R_{R} and parts disposed on the negative side in the Y-direction with respect to the region R_{R}.

In FIG. 3, two insulating members 105 adjacent to one another in the Y-direction are illustrated as insulating members 105a, 105b. In addition, in FIG. 3, a position of a side surface of the insulating member 105a on an insulating member 105b side in the Y-direction is illustrated as a position Y1, and a position of a side surface of the insulating member 105b on an insulating member 105a side in the Y-direction is illustrated as a position Y2. Each of the via-wirings 102, 103, 104 has an end portion on one side in the Y-direction disposed between the positions Y1, Y2 and an end portion on the other side in the Y-direction not disposed between the positions Y1, Y2.

In the example of FIG. 3, the via-wiring 104 protrudes from the region R_{R} to the positive side in the Y-direction, and a part of the via-wiring 104 digs into the insulating member 105a. Therefore, the side surface of the insulating member 105a on the negative side in the Y-direction has two linear parts that are disposed at the position Y1 and extending in the X-direction and a curved part disposed between these two parts. This curved part is continuous with the two linear parts and formed along a part of an outer peripheral surface of the via-wiring 104 (a part disposed outside the region R_{R}).

In addition, in the example of FIG. 3, the via-wirings 102, 103 protrude from the region R_{R} to the negative side in the Y-direction, and parts of the via-wirings 102, 103 dig into the insulating member 105b. Therefore, the side surface of the insulating member 105b on the positive side in the Y-direction has three linear parts that are disposed at the position Y2 and extend in the X-direction and two curved parts, each of which is disposed between two out of these three parts. One of these two curved parts is disposed between the first and second linear parts counting from a negative side in the X-direction, and it is continuous with these two parts and formed along a part of an outer peripheral surface of the via-wiring 102 (a part disposed outside the region R_{R}). The other of these two curved parts is disposed between the second and third linear parts counting from the negative side in the X-direction, and it is continuous with these two parts and formed along a part of an outer peripheral surface of the via-wiring 103 (a part disposed outside the region R_{R}).

The wiring 110 functions as, for example, the write word line WWL (FIG. 1). The wiring 110 includes, for example, a barrier conductive film 111 of titanium nitride (TiN) or the like and a conductive film 112 of tungsten (W).

The wiring 120 functions as, for example, the read word line RWL (FIG. 1). The wiring 120 includes, for example, a barrier conductive film 121 of titanium nitride (TiN) or the like and a conductive film 122 of tungsten (W).

The transistor structure 130 includes a semiconductor layer 131, an insulating layer 132, a conductive layer 133, and an insulating layer 134. The semiconductor layer 131 is connected to a part of the outer peripheral surface of the via-wiring 102 and extends in the X-direction in the above-described region R_{R}. The insulating layer 132 is disposed on an upper surface, a lower surface, both side surfaces in the Y-direction, and a side surface on one side (wiring 110 side) in the X-direction of the semiconductor layer 131. The conductive layer 133 is disposed on an upper surface, a lower surface, both side surfaces in the Y-direction, and a side surface on one side (wiring 110 side) in the X-direction of the insulating layer 132. The insulating layer 134 is disposed on an upper surface, a lower surface, and both side surfaces in the Y-direction of the conductive layer 133.

On an XY cross-sectional surface exemplified in FIG. 3, a side surface of the semiconductor layer 131 on the other side (wiring 120 side) in the X-direction may be formed along a circle with a center position of the via-wiring 102 or the via-wiring 104 as its center. Additionally, the side surfaces of the semiconductor layer 131, the insulating layer 132, and the conductive layer 133 on one side (wiring 110 side) in the X-direction may be linearly formed along a side surface of the wiring 110. Furthermore, both side surfaces of the semiconductor layer 131, the insulating layer 132, the conductive layer 133, and the insulating layer 134 in the Y-direction may be linearly formed along the side surfaces of the insulating members 105.

The semiconductor layer 131 functions as, for example, a channel region of the write transistor WTr (FIG. 1). The semiconductor layer 131 may be, for example, a semiconductor containing at least one element of gallium (Ga) or aluminum (Al), indium (In), zinc (Zn), and oxygen (O) or may be another oxide semiconductor. A plurality of semiconductor layers 131 arranged in the Z-direction are connected in common to the via-wiring 102 extending in the Z-direction.

The insulating layer 132 functions as, for example, a gate insulating film of the write transistor WTr (FIG. 1). The insulating layer 132 contains, for example, silicon oxide (SiO₂) or the like.

The conductive layer 133 functions as, for example, the gate electrode of the write transistor WTr (FIG. 1). The conductive layer 133 contains, for example, a conductive material, such as titanium nitride (TiN), or a conductive oxide, such as indium tin oxide (ITO). The conductive layer 133 is opposed to the upper surface, the lower surface, both side surfaces in the Y-direction, and the side surface on one side (wiring 110 side) in the X-direction of the semiconductor layer 131 via the insulating layer 132. The side surface of the conductive layer 133 on one side (wiring 110 side) in the X-direction is connected to the wiring 110.

The insulating layer 134 contains, for example, silicon oxide (SiO₂) or the like.

The transistor structure 140 includes a semiconductor layer 141, an insulating layer 142, a conductive layer 143, and an insulating layer 144. The semiconductor layer 141 is connected to a part of the outer peripheral surface of the via-wiring 103 and extends in the X-direction in the above-described region R_{R}. The insulating layer 142 is disposed on an upper surface, a lower surface, both side surfaces in the Y-direction, and a side surface on one side (wiring 120 side) in the X-direction of the semiconductor layer 141. The conductive layer 143 is disposed on an upper surface, a lower surface, both side surfaces in the Y-direction, and a side surface on one side (wiring 120 side) in the X-direction of the insulating layer 142. The insulating layer 144 is disposed on an upper surface, a lower surface, and both side surfaces in the Y-direction of the conductive layer 143.

On the XY cross-sectional surface exemplified in FIG. 3, the side surfaces of the semiconductor layer 141, the insulating layer 142, and the conductive layer 143 on one side (wiring 120 side) in the X-direction may be linearly formed along a side surface of the wiring 120. In addition, both side surfaces of the semiconductor layer 141, the insulating layer 142, the conductive layer 143, and the insulating layer 144 in the Y-direction may be linearly formed along the side surfaces of the insulating members 105.

The semiconductor layer 141 functions as, for example, a channel region of the select transistor STr (FIG. 1). The semiconductor layer 141 may be, for example, a semiconductor containing at least one element of gallium (Ga) or aluminum (Al), indium (In), zinc (Zn), and oxygen (O) or may be another oxide semiconductor. A plurality of semiconductor layers 141 arranged in the Z-direction are connected in common to the via-wiring 103 extending in the Z-direction.

The insulating layer 142 functions as, for example, a gate insulating film of the select transistor STr (FIG. 1). The insulating layer 142 contains, for example, silicon oxide (SiO₂) or the like.

The conductive layer 143 functions as, for example, the gate electrode of the select transistor STr (FIG. 1). The conductive layer 143 contains, for example, a conductive material, such as titanium nitride (TiN), or a conductive oxide, such as indium tin oxide (ITO). The conductive layer 143 is opposed to the upper surface, the lower surface, both side surfaces in the Y-direction, and the side surface on one side (wiring 120 side) in the X-direction of the semiconductor layer 141 via the insulating layer 142. The side surface on one side (wiring 120 side) in the X-direction of the conductive layer 143 is connected to the wiring 120.

The insulating layer 144 contains, for example, silicon oxide (SiO₂) or the like.

The transistor structure 150 includes a conductive layer 151, an insulating layer 152, a semiconductor layer 153, and an insulating layer 154. The conductive layer 151 is connected to the side surface of the semiconductor layer 131 on one side (wiring 120 side) in the X-direction and extends in the X-direction in the above-described region R_{R}. The insulating layer 152 is disposed on an upper surface, a lower surface, both side surfaces in the Y-direction, and a side surface on one side (wiring 120 side) in the X-direction of the conductive layer 151. The semiconductor layer 153 is connected to a part of the outer peripheral surface of the via-wiring 104 and disposed on an upper surface, a lower surface, both side surfaces in the Y-direction, and a side surface on one side (wiring 120 side) in the X-direction of the insulating layer 152. The insulating layer 154 is disposed on an upper surface, a lower surface, and both side surfaces in the Y-direction of the semiconductor layer 153.

On the XY cross-sectional surface exemplified in FIG. 3, the side surfaces of the conductive layer 151 and the insulating layer 152 on one side (wiring 120 side) in the X-direction may be formed along a circle with a center position of the via-wiring 104 as its center. A side surface of the conductive layer 151 on the other side (wiring 110 side) in the X-direction may be formed along a circle with the center position of the via-wiring 102 or the via-wiring 104 as its center. In addition, the side surfaces of the conductive layer 151, the insulating layer 152, the semiconductor layer 153, and the insulating layer 154 on one side in the Y-direction may be linearly formed along the side surface of the insulating member 105. Further, the side surfaces of the conductive layer 151 and the insulating layer 152 on the other side in the Y-direction may each have two linear parts extending in the X-direction along the side surface of the insulating member 105 and a curved part disposed between these two parts. This curved part may be continuous with the two linear parts and formed along a part of the outer peripheral surface of the via-wiring 104 (a part disposed inside the region R_{R}).

The conductive layer 151 functions as, for example, the storage node SN (FIG. 1) and the gate electrode of the read transistor RTr (FIG. 1). The conductive layer 151 contains, for example, a conductive material, such as titanium nitride (TiN), or a conductive oxide, such as indium tin oxide (ITO). The conductive layer 151 is connected to the side surface of the semiconductor layer 131 on one side (wiring 120 side) in the X-direction.

The insulating layer 152 functions as, for example, a gate insulating film of the read transistor RTr (FIG. 1). The insulating layer 152 is continuous with the insulating layer 132 and contains a material similar to that of the insulating layer 132. The insulating layer 152 is formed simultaneously, for example, when the insulating layer 132 is formed.

The semiconductor layer 153 functions as, for example, a channel region of the read transistor RTr (FIG. 1). The semiconductor layer 153 is continuous with the semiconductor layer 141 and contains a material similar to that of the semiconductor layer 141. The semiconductor layer 153 is formed simultaneously, for example, when the semiconductor layer 141 is formed. A plurality of semiconductor layers 153 arranged in the Z-direction are connected in common to the via-wiring 104 extending in the Z-direction. The semiconductor layer 153 is opposed to the upper surface, the lower surface, both side surfaces in the Y-direction, and the side surface on one side (wiring 120 side) in the X-direction of the conductive layer 151 via the insulating layer 152.

The insulating layer 154 contains, for example, silicon oxide (SiO₂) or the like.

### Manufacturing Method

FIGS. 5 to 98 are schematic cross-sectional views for describing a manufacturing method of the semiconductor memory device according to the first embodiment. FIGS. 5, 7, 9, 11, 13, 15, 17, 19, 21, 23, 25, 27, 29, 31, 33, 35, 37, 39, 41, 43, 45, 47, 49, 51, 53, 55, 57, 59, 61, 63, 65, 67, 69, 71, 73, 75, 77, 79, 81, 83, 85, 87, 89, 91, 93, 95, and 97 illustrate cross-sectional surfaces corresponding to FIGS. 3, 6, 8, 10, 12, 14, 16, 18, 20, 22, 24, 26, 28, 30, 32, 34, 36, 38, 40, 42, 44, 46, 48, 50, 52, 54, 56, 58, 60, 62, 64, 66, 68, 70, 72, 74, 76, 78, 80, 82, 84, 86, 88, 90, 92, 94, 96 and 98, illustrate cross-sectional surfaces corresponding to FIG. 4.

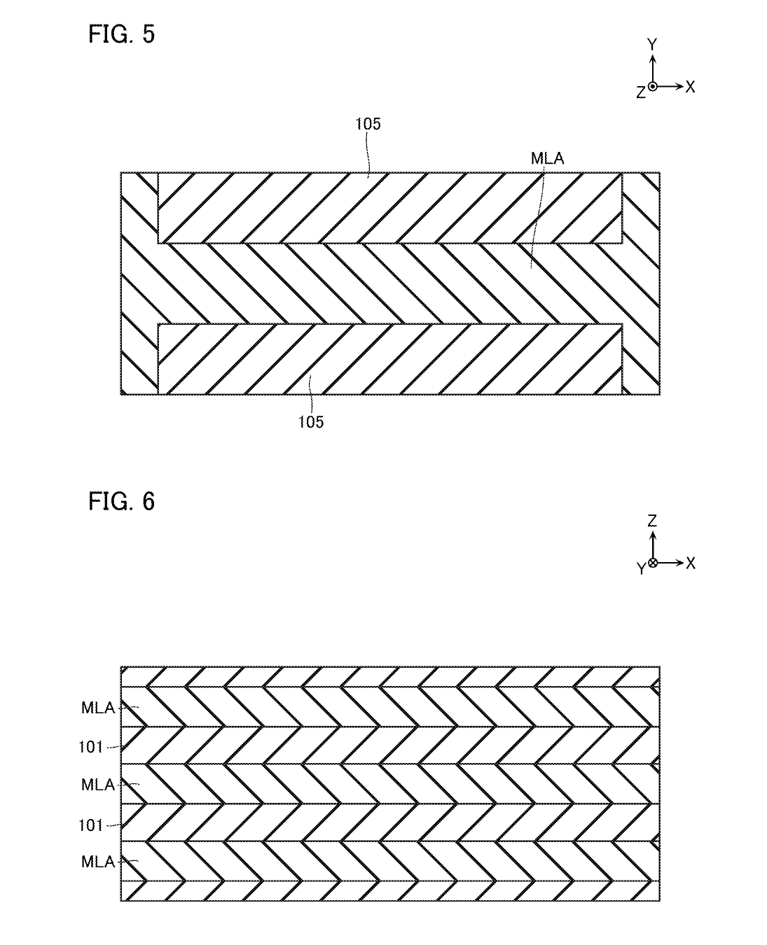

In the manufacturing method, for example, as illustrated in FIG. 6, a plurality of insulating layers 101 and a plurality of sacrifice layers MLA are alternately formed. The sacrifice layers MLA contain, for example, silicon nitride (Si₃N₄) or the like. This process is performed by, for example, Chemical Vapor Deposition (CVD) or the like.

Next, for example, as illustrated in FIG. 5, the insulating members 105 are formed. In this process, for example, openings are formed at positions corresponding to the insulating members 105. The openings extend in the Z-direction and penetrate the plurality of insulating layers 101 and the plurality of sacrifice layers MLA arranged in the Z-direction. This process is performed by, for example, Reactive Ion Etching (RIE) or the like. After the openings are formed, the insulating members 105 are formed. This process is performed by, for example, CVD or the like.

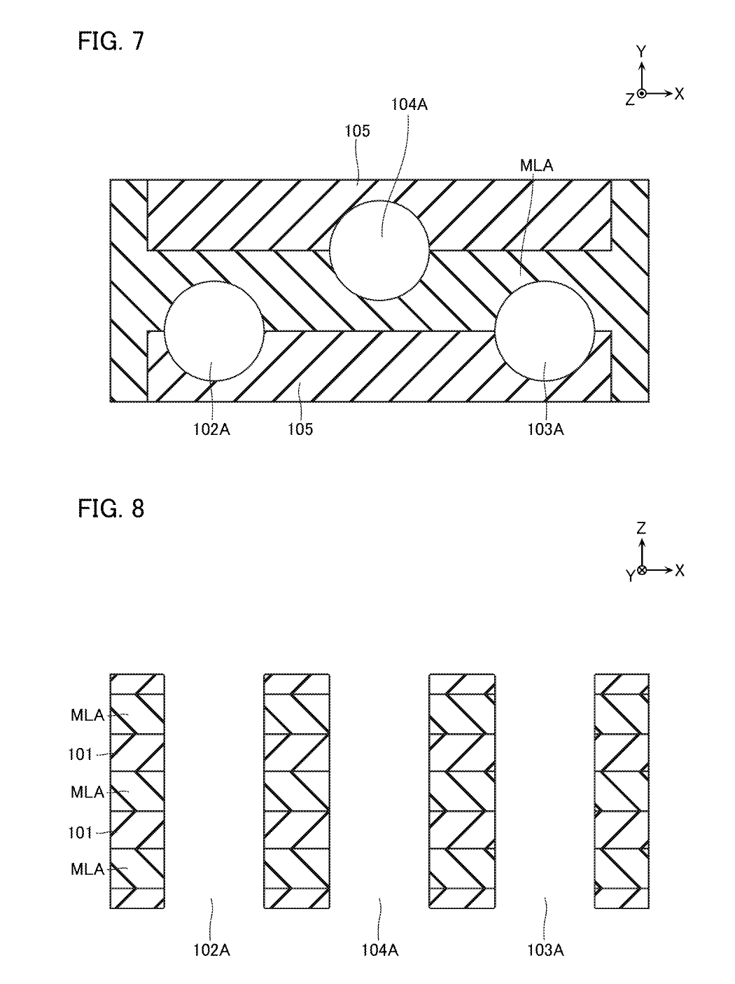

Next, for example, as illustrated in FIG. 7 and FIG. 8, openings 102A, 103A, 104A are formed at positions corresponding to the via-wirings 102, 103, 104, respectively. The openings 102A, 103A, 104A extend in the Z-direction. Each of the openings 102A, 103A, 104A has a part penetrating the plurality of insulating layers 101 and the plurality of sacrifice layers MLA arranged in the Z-direction and a part penetrating the insulating members 105. This process is performed by, for example, RIE or the like.

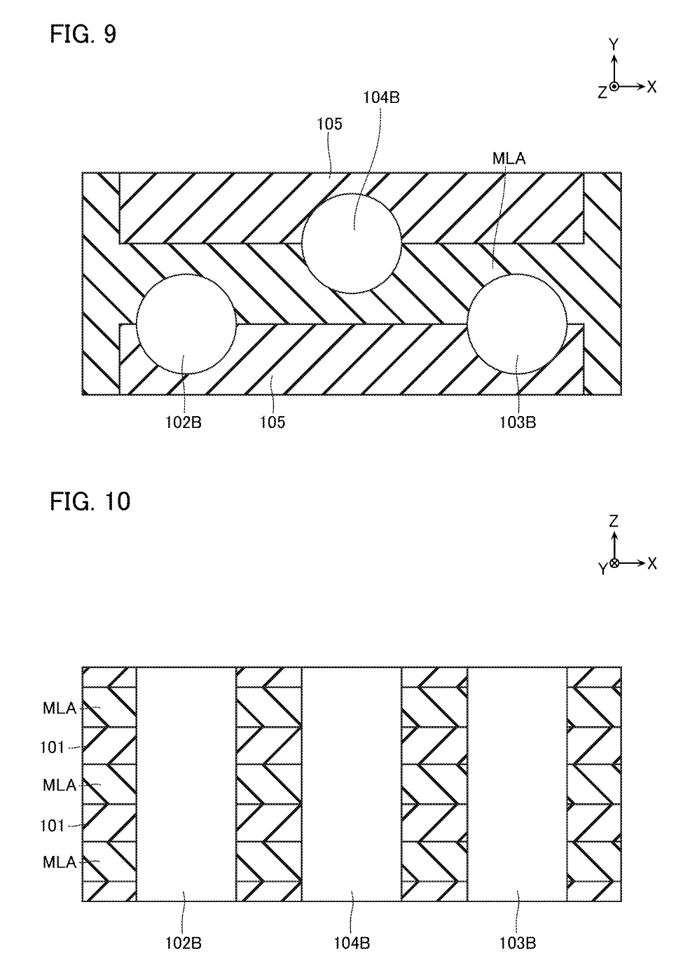

Next, for example, as illustrated in FIG. 9 and FIG. 10, sacrifice layers 102B, 103B, 104B of silicon (Si) or the like are formed inside the openings 102A, 103A, 104A, respectively. This process is performed by, for example, CVD or the like. Although not illustrated, after this process is completed, an insulating layer or the like is formed at upper portions of the sacrifice layers 102B, 103B, 104B.

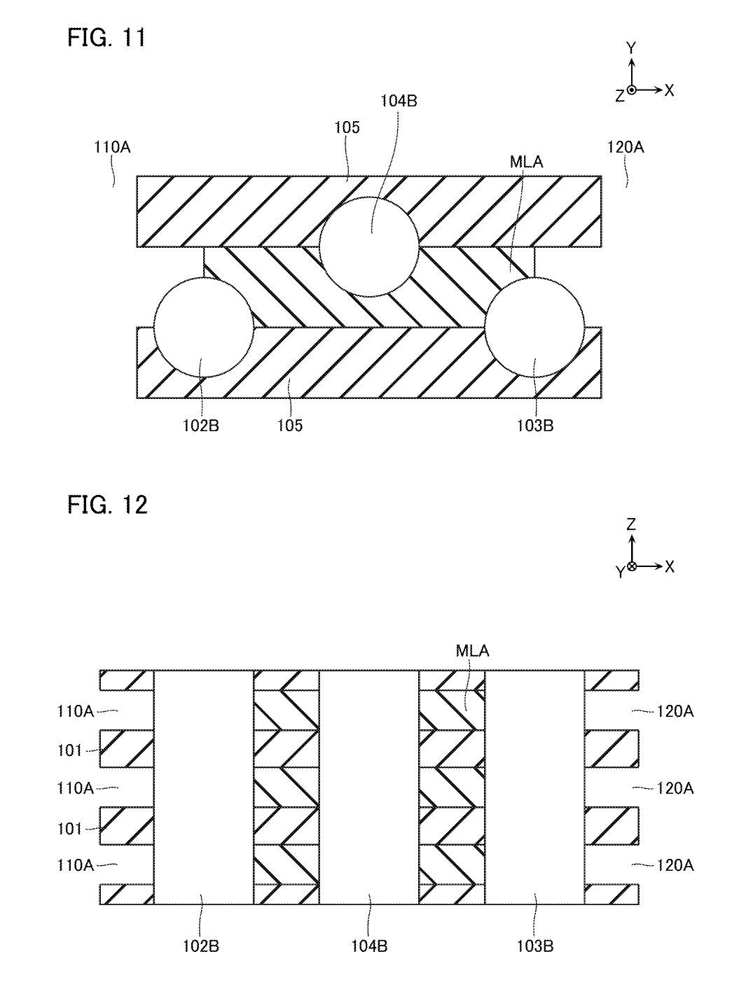

Next, for example, as illustrated in FIG. 11 and FIG. 12, openings 110A, 120A are formed at positions corresponding to the wirings 110, 120, respectively.

In this process, for example, trenches extending in the Y-direction and the Z-direction are formed at the proximity of the positions corresponding to the wirings 110, 120. These trenches penetrate the plurality of insulating layers 101 and the plurality of sacrifice layers MLA arranged in the Z-direction and separate these configurations in the X-direction. This process is performed by, for example, RIE or the like.

Next, the openings 110A, 120A are formed at the positions corresponding to the wirings 110, 120, respectively. Parts of upper surfaces and parts of lower surfaces of the insulating layers 101, parts of side surfaces in the Y-direction of the insulating members 105, and parts of side surfaces in the X-direction of the sacrifice layers MLA are exposed inside the openings 110A, 120A. A part of an outer peripheral surface of the sacrifice layer 102B is exposed inside the openings 110A. In addition, a part of an outer peripheral surface of the sacrifice layer 103B is exposed inside the openings 120A. In this process, for example, parts of the sacrifice layers MLA are selectively removed via the above-described trenches. This process is performed by, for example, wet etching or the like.

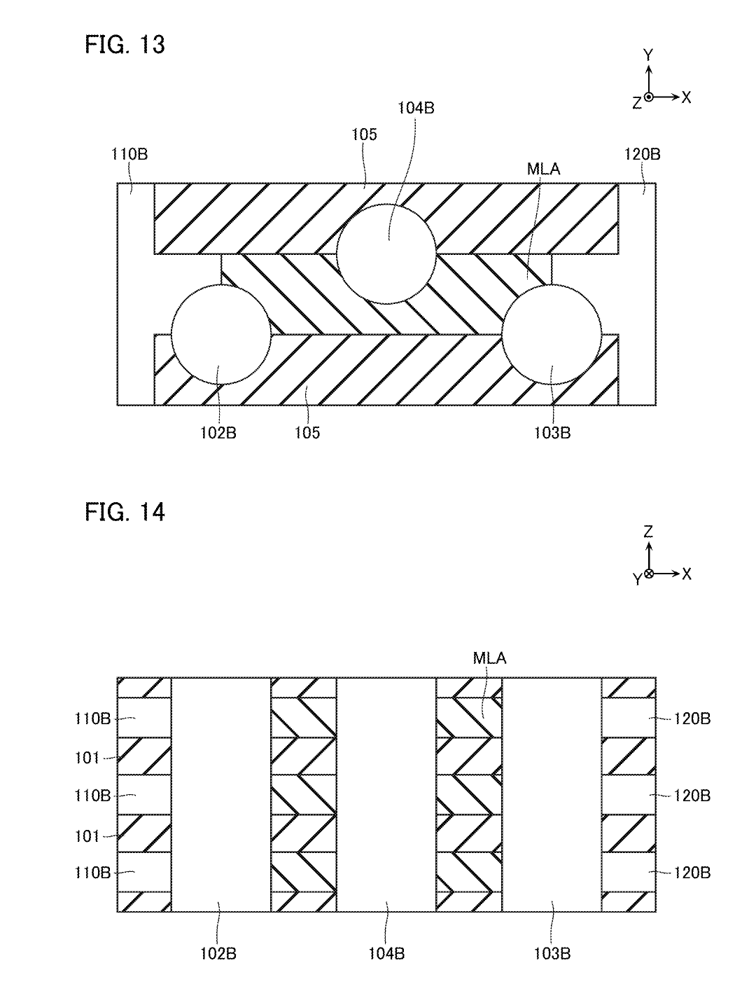

Next, for example, as illustrated in FIG. 13 and FIG. 14, sacrifice layers 110B, 120B of carbon (C) or the like are filled inside the openings 110A, 120A, respectively. This process is performed by, for example, CVD or the like.

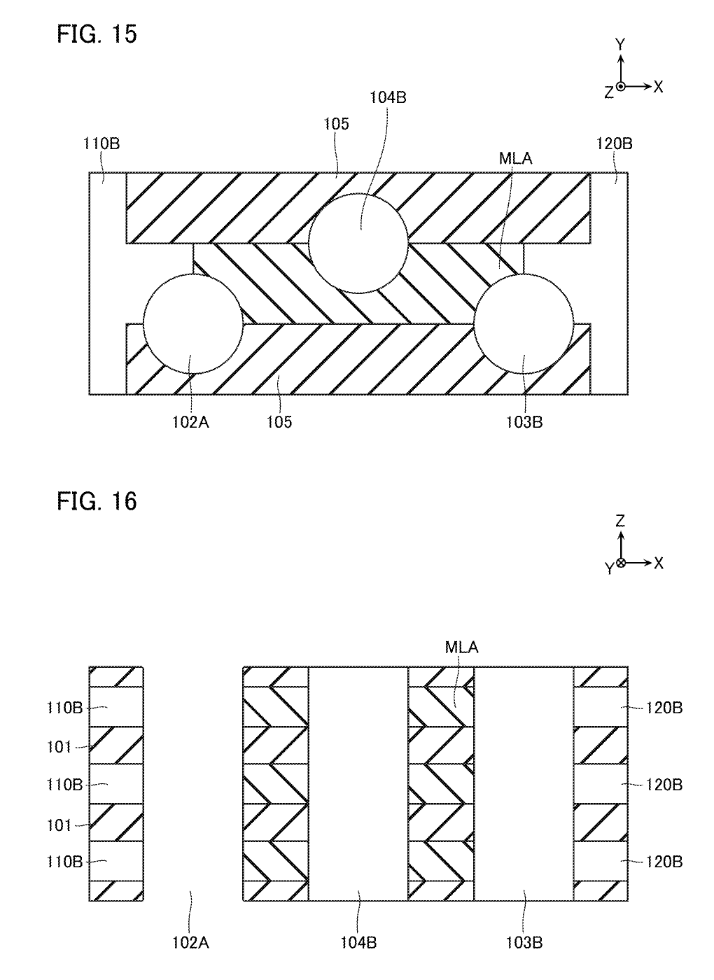

Next, for example, as illustrated in FIG. 15 and FIG. 16, the sacrifice layer 102B is removed. This process is performed by, for example, wet etching or the like.

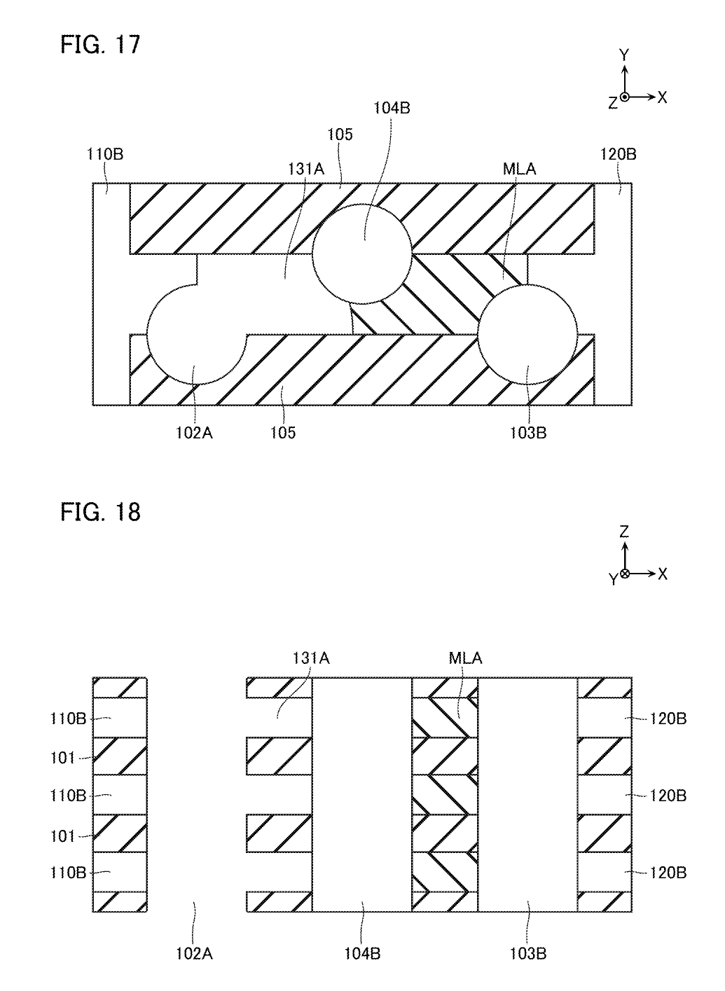

Next, for example, as illustrated in FIG. 17 and FIG. 18, openings 131A are formed at positions corresponding to the semiconductor layers 131. Parts of the upper surfaces and parts of the lower surfaces of the insulating layers 101, parts of the side surfaces in the X-direction of the sacrifice layers MLA, parts of the side surfaces in the Y-direction of the insulating members 105, a part of an outer peripheral surface of the sacrifice layer 104B, and parts of side surfaces in the X-direction of the sacrifice layers 110B are exposed inside the openings 131A. In this process, for example, parts of the sacrifice layers MLA are selectively removed via the opening 102A. This process is performed by, for example, wet etching or the like.

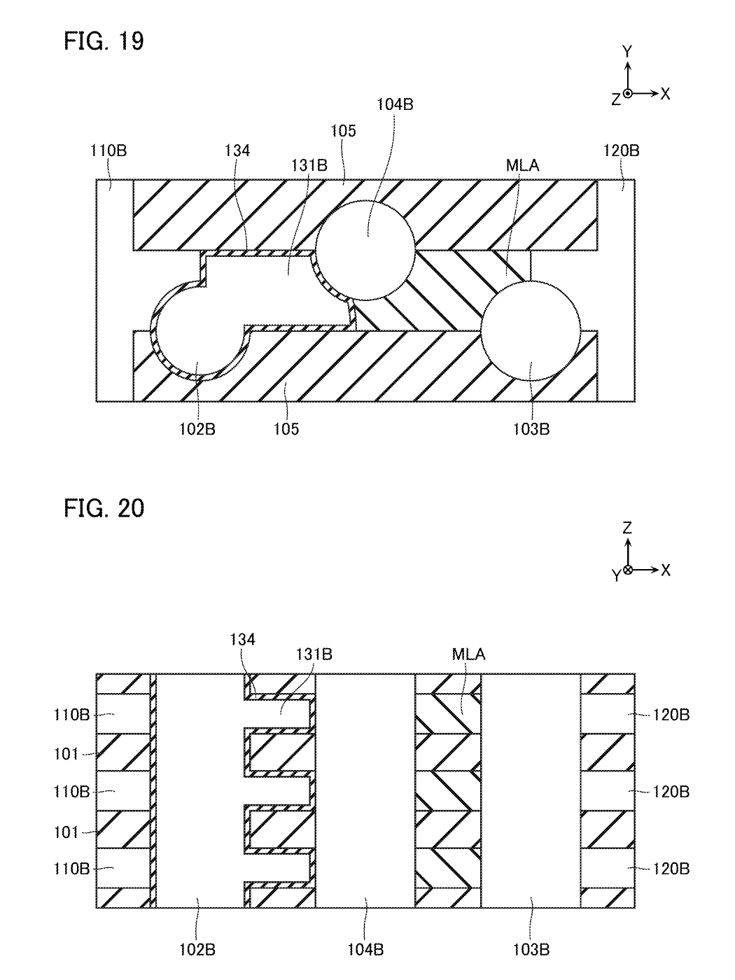

Next, for example, as illustrated in FIG. 19 and FIG. 20, the insulating layer 134 is formed inside the openings 131A and the opening 102A. The insulating layer 134 is formed on parts of the upper surfaces and parts of the lower surfaces of the insulating layers 101, exposed surfaces of the insulating layers 101 to the opening 102A, parts of the side surfaces of the sacrifice layers MLA in the X-direction, parts of the side surfaces of the insulating members 105 in the Y-direction, a part of the outer peripheral surface of the sacrifice layer 104B, and parts of the side surfaces of the sacrifice layers 110B in the X-direction. In addition, the openings 131A are filled with sacrifice layers 131B of silicon (Si) or the like, and the opening 102A is filled with a sacrifice layer 102B of silicon (Si) or the like. This process is performed by, for example, CVD or the like. Although not illustrated, after this process is completed, an insulating layer or the like is formed at an upper portion of the sacrifice layer 102B.

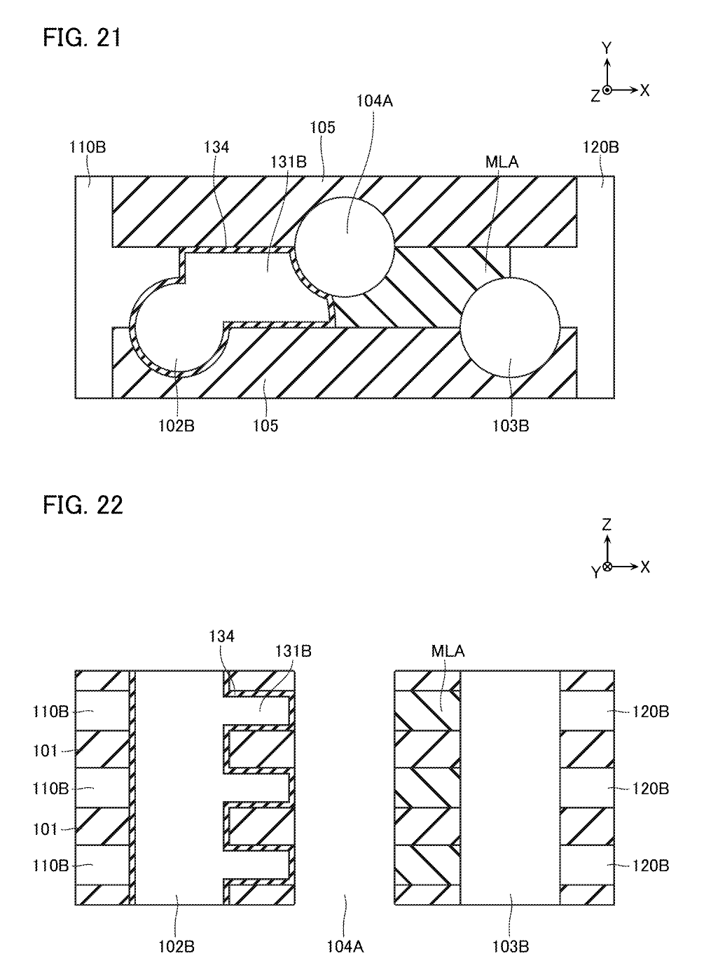

Next, for example, as illustrated in FIG. 21 and FIG. 22, the sacrifice layer 104B is removed. This process is performed by, for example, wet etching or the like.

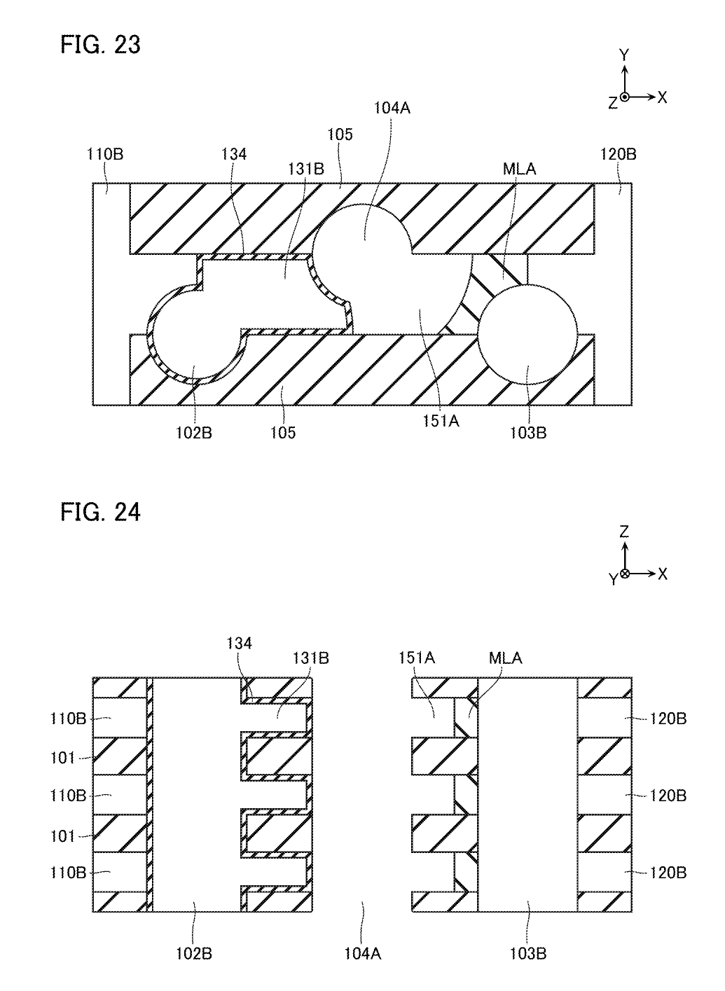

Next, for example, as illustrated in FIG. 23 and FIG. 24, openings 151A are formed at positions corresponding to parts of the conductive layers 151. Parts of the upper surfaces and parts of the lower surfaces of the insulating layers 101, parts of the side surfaces in the X-direction of the sacrifice layers MLA, parts of the side surfaces in the Y-direction of the insulating members 105, and a part of a side surface in the X-direction of the insulating layer 134 are exposed inside the openings 151A. In this process, for example, parts of the sacrifice layers MLA are selectively removed via the opening 104A. This process is performed by, for example, wet etching or the like.

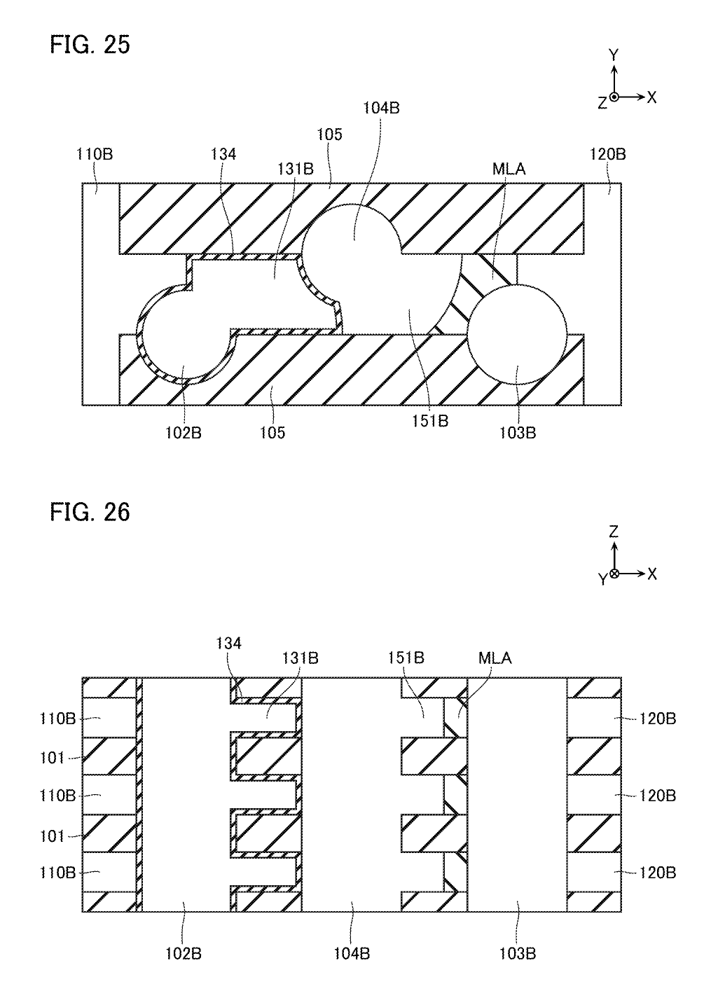

Next, for example, as illustrated in FIG. 25 and FIG. 26, the openings 151A are filled with sacrifice layers 151B of silicon (Si) or the like, and the opening 104A is filled with a sacrifice layer 104B of silicon (Si) or the like. This process is performed by, for example, CVD or the like. Although not illustrated, after this process is completed, an insulating layer or the like is formed at an upper portion of the sacrifice layer 104B.

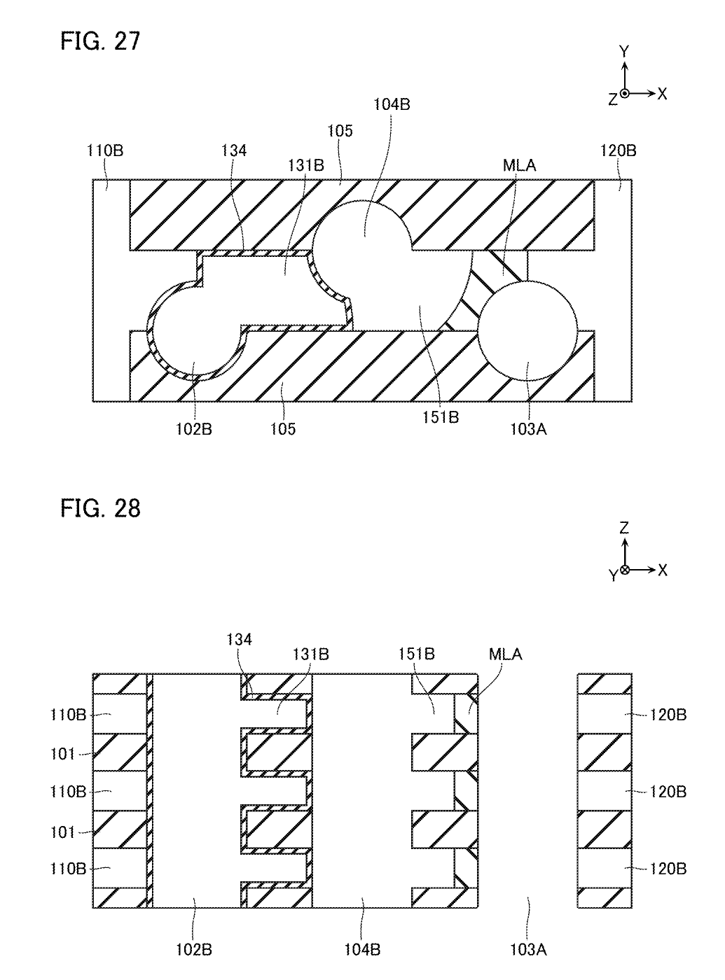

Next, for example, as illustrated in FIG. 27 and FIG. 28, the sacrifice layer 103B is removed. This process is performed by, for example, wet etching or the like.

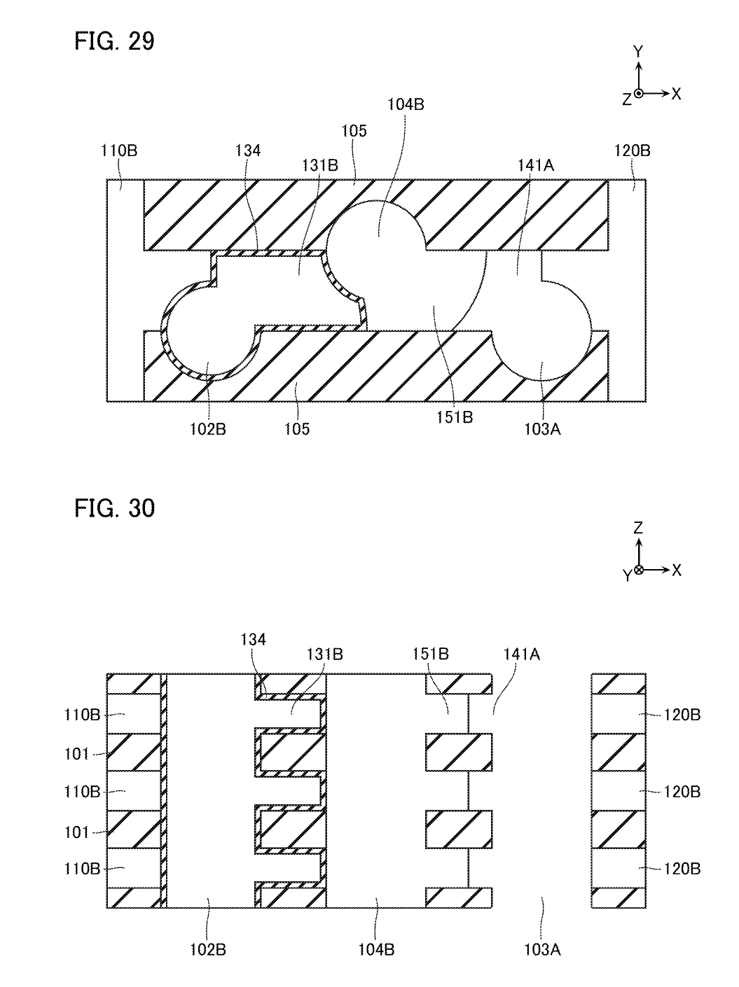

Next, for example, as illustrated in FIG. 29 and FIG. 30, openings 141A are formed at positions corresponding to the semiconductor layers 141. Parts of the upper surfaces and parts of the lower surfaces of the insulating layers 101, side surfaces in the X-direction of the sacrifice layers 151B, parts of the side surfaces in the Y-direction of the insulating members 105, and parts of side surfaces in the X-direction of the sacrifice layers 120B are exposed inside the openings 141A. In this process, for example, the sacrifice layers MLA are selectively removed via the opening 103A. This process is performed by, for example, wet etching or the like.

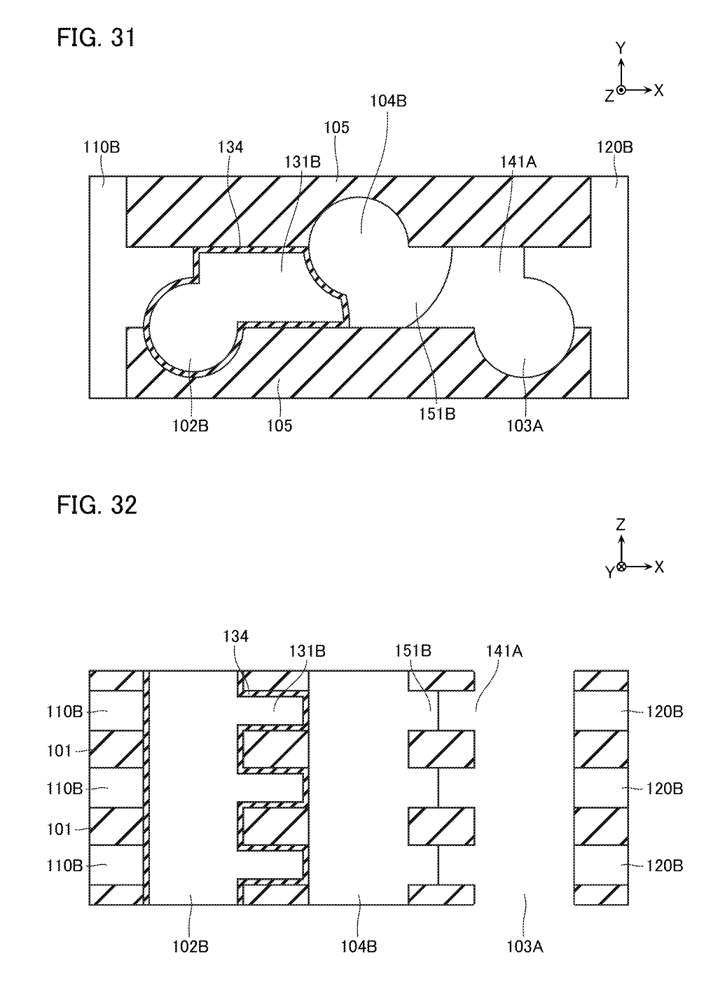

Next, for example, as illustrated in FIG. 31 and FIG. 32, parts of the sacrifice layers 151B are selectively removed via the openings 141A, 103A. This process is performed by, for example, wet etching or the like.

Here, in the process described with reference to FIG. 23 and FIG. 24, it is necessary to expose parts of the side surfaces of two insulating members 105 adjacent to one another in the Y-direction to the inside of the opening 151A. In view of this, there is a risk that the opening 151A will become larger than necessary, resulting in the channel length of the read transistor RTr becoming too long or the channel length of the select transistor STr becoming too short. Therefore, in the embodiment, using the process described with reference to FIG. 31 and FIG. 32, a part of the sacrifice layer 151B is selectively removed, thereby adjusting the channel lengths of the read transistor RTr and the select transistor STr.

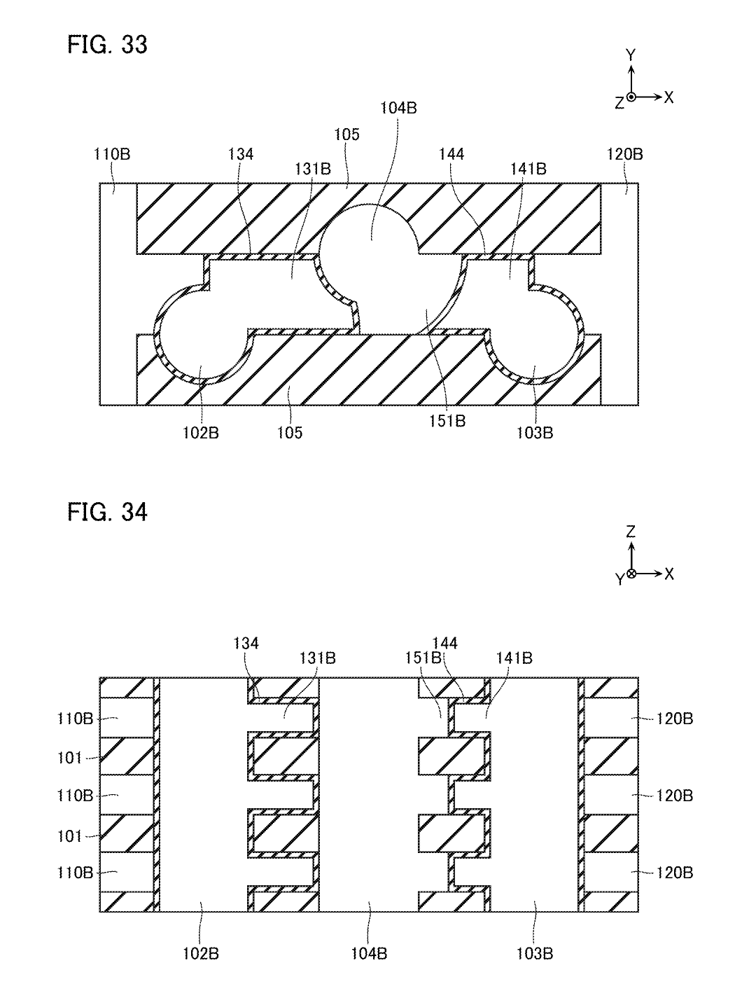

Next, for example, as illustrated in FIG. 33 and FIG. 34, the insulating layer 144 is formed inside the openings 141A and the opening 103A. The insulating layer 144 is formed on parts of the upper surfaces and parts of the lower surfaces of the insulating layers 101, exposed surfaces of the insulating layers 101 to the opening 103A, the side surfaces of the sacrifice layers 151B in the X-direction, parts of the side surfaces of the insulating members 105 in the Y-direction, and parts of the side surfaces of the sacrifice layers 120B in the X-direction. In addition, the openings 141A are filled with a sacrifice layers 141B of silicon (Si) or the like, and the opening 103A is filled with the sacrifice layer 103B of silicon (Si) or the like. This process is performed by, for example, CVD or the like. Although not illustrated, after this process is completed, an insulating layer or the like is formed at an upper portion of the sacrifice layer 103B.

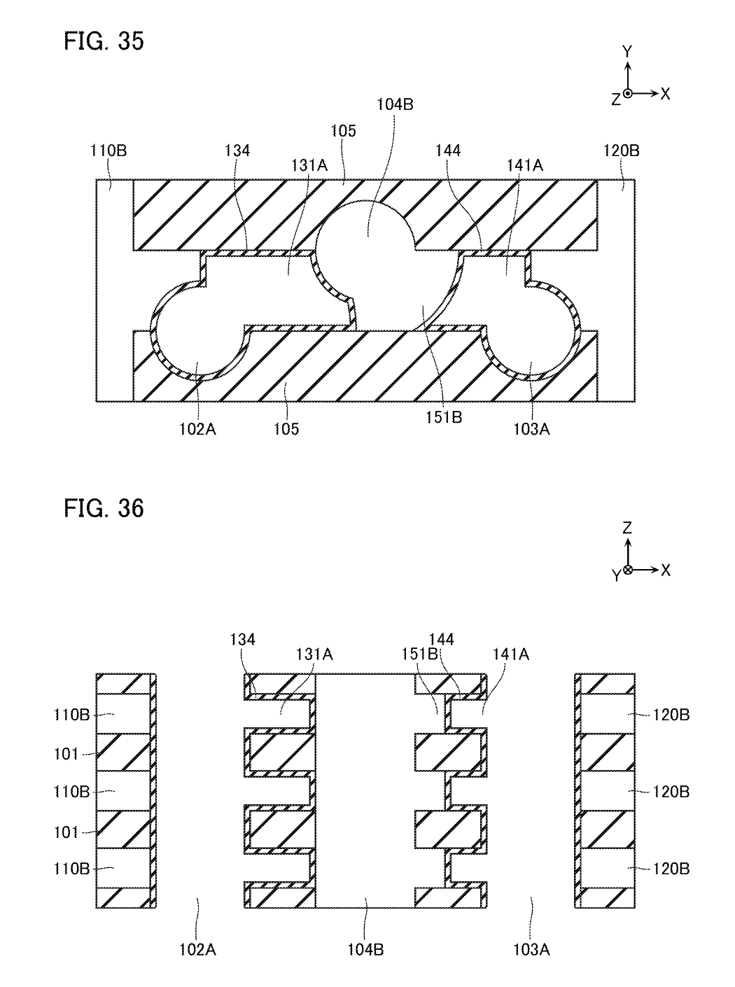

Next, for example, as illustrated in FIG. 35 and FIG. 36, the sacrifice layers 102B, 103B, 131B, 141B are removed. This process is performed by, for example, wet etching or the like.

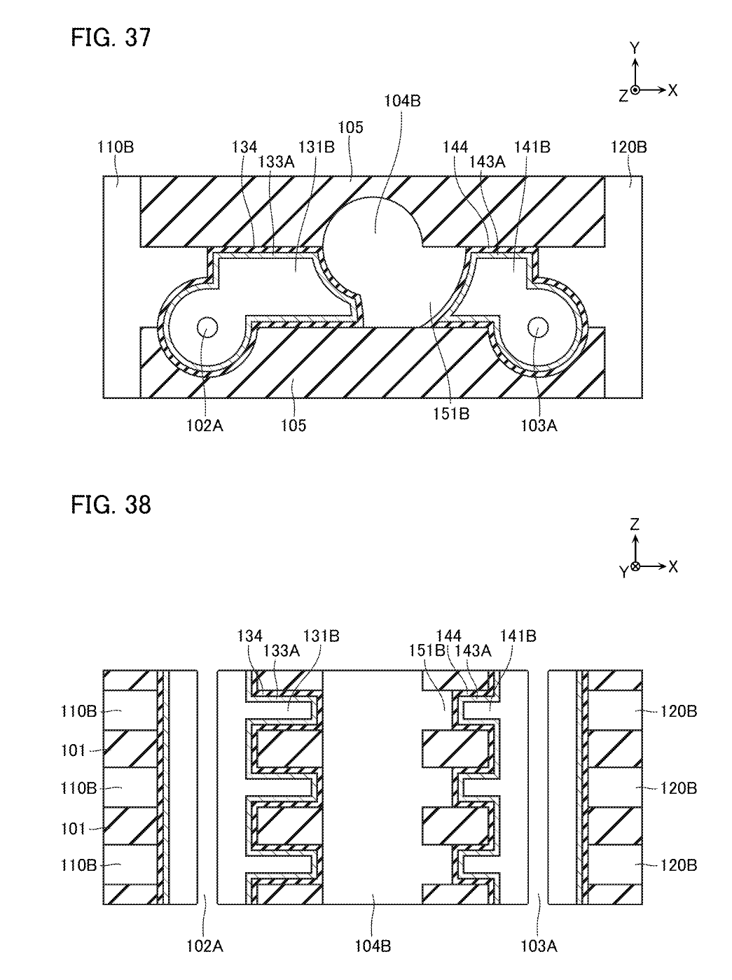

Next, for example, as illustrated in FIG. 37 and FIG. 38, a conductive layer 133A and the sacrifice layer 131B are formed inside the openings 131A and the opening 102A. Similarly, a conductive layer 143A and the sacrifice layer 141B are formed inside the openings 141A and the opening 103A. The openings 131A are filled with the sacrifice layer 131B, while the opening 102A is not filled with the sacrifice layer 131B. Similarly, the openings 141A are filled with the sacrifice layer 141B, while the opening 103A is not filled with the sacrifice layer 141B. This process is performed by, for example, CVD or the like.

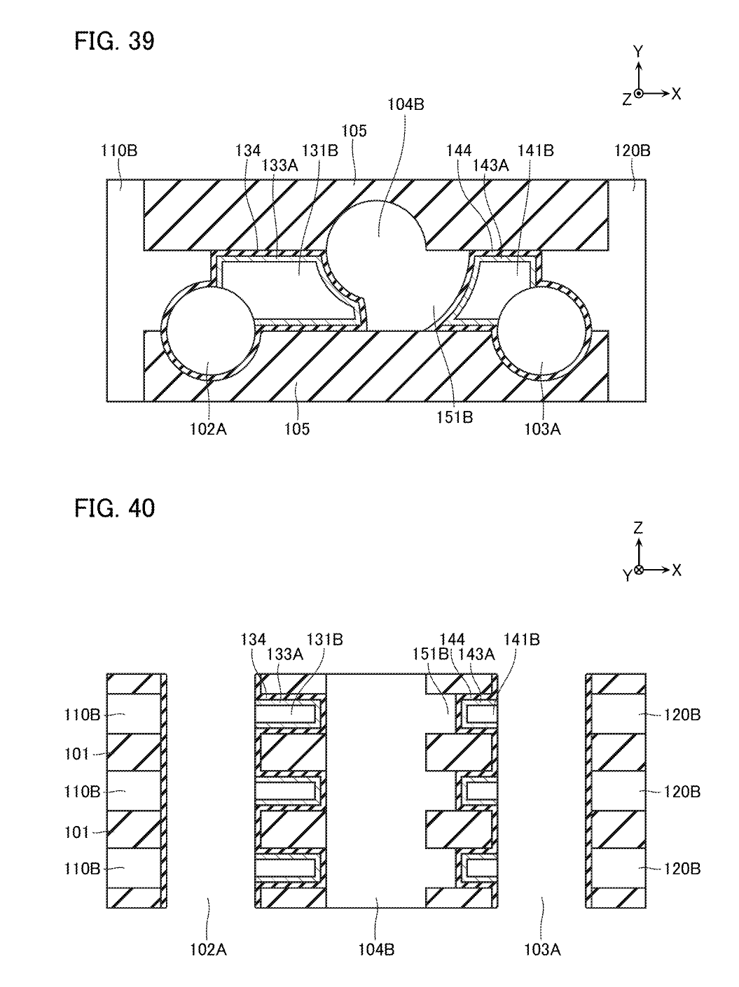

Next, for example, as illustrated in FIG. 39 and FIG. 40, parts of the conductive layers 133A, 143A are removed. In this process, for example, parts of the sacrifice layers 131B, 141B that are disposed on inner peripheral surfaces of the openings 102A, 103A are removed to expose parts of the conductive layers 133A, 143A. Next, parts of the conductive layers 133A, 143A that are disposed on the inner peripheral surfaces of the openings 102A, 103A are removed to separate the conductive layers 133A, 143A in the Z-direction. This process is performed by, for example, wet etching or the like.

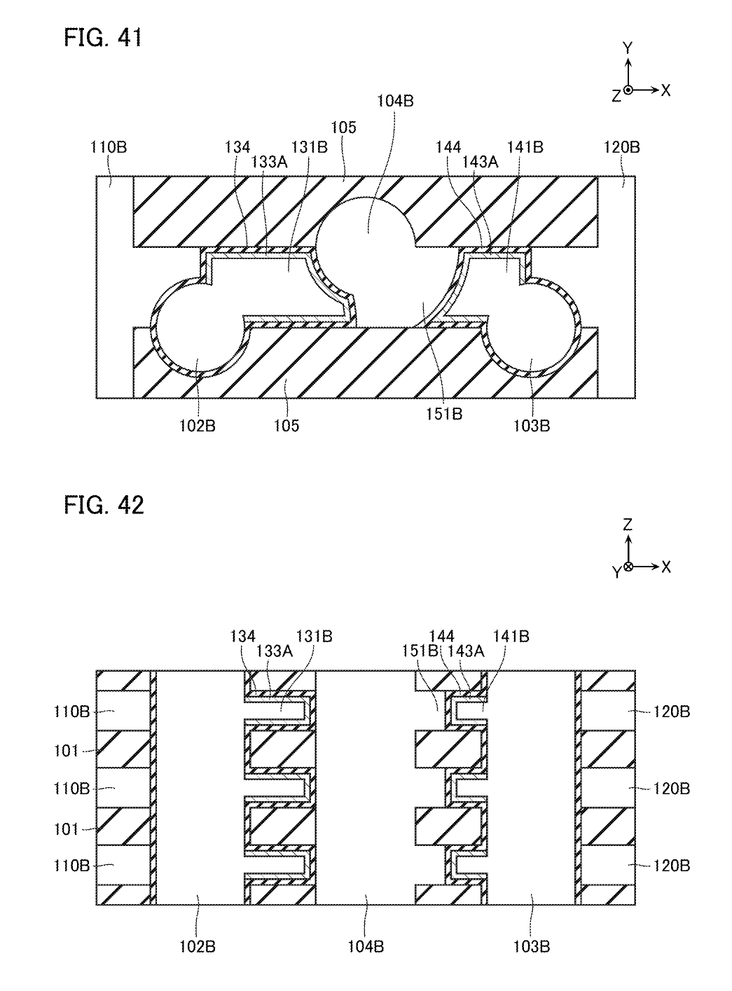

Next, for example, as illustrated in FIG. 41 and FIG. 42, the openings 102A, 103A are filled with sacrifice layers 102B, 103B of silicon (Si) or the like, respectively. This process is performed by, for example, CVD or the like. Although not illustrated, after this process is completed, an insulating layer or the like is formed at upper portions of the sacrifice layers 102B, 103B.

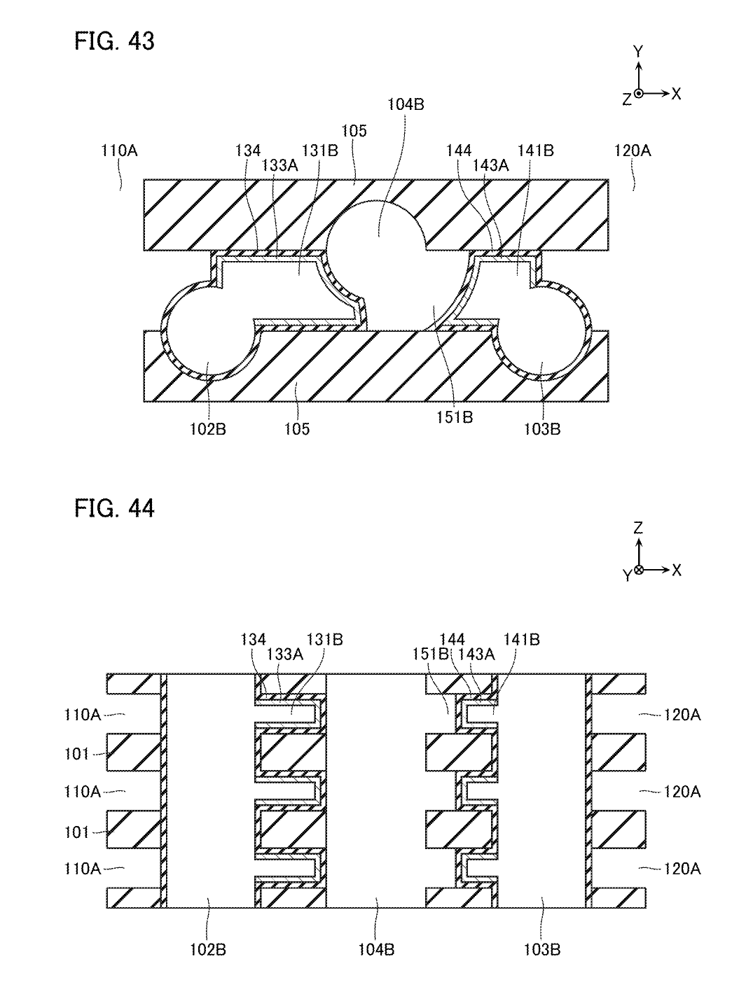

Next, for example, as illustrated in FIG. 43 and FIG. 44, the sacrifice layers 110B, 120B are removed. This process is performed by, for example, wet etching or the like.

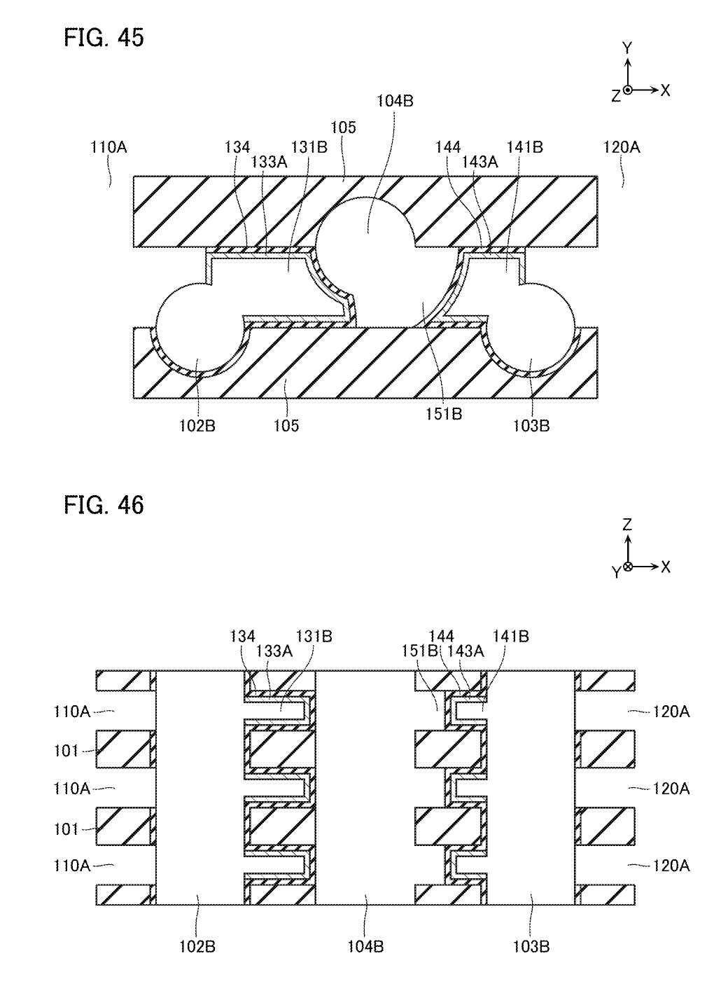

Next, for example, as illustrated in FIG. 45 and FIG. 46, parts of the insulating layer 134 are removed via the openings 110A to expose side surfaces of the conductive layers 133A on one side in the X-direction and parts of the outer peripheral surface of the sacrifice layer 102B. Similarly, parts of the insulating layer 144 are removed via the openings 120A to expose side surfaces of the conductive layers 143A on one side in the X-direction and parts of the outer peripheral surface of the sacrifice layer 103B. This process is performed by, for example, wet etching or the like.

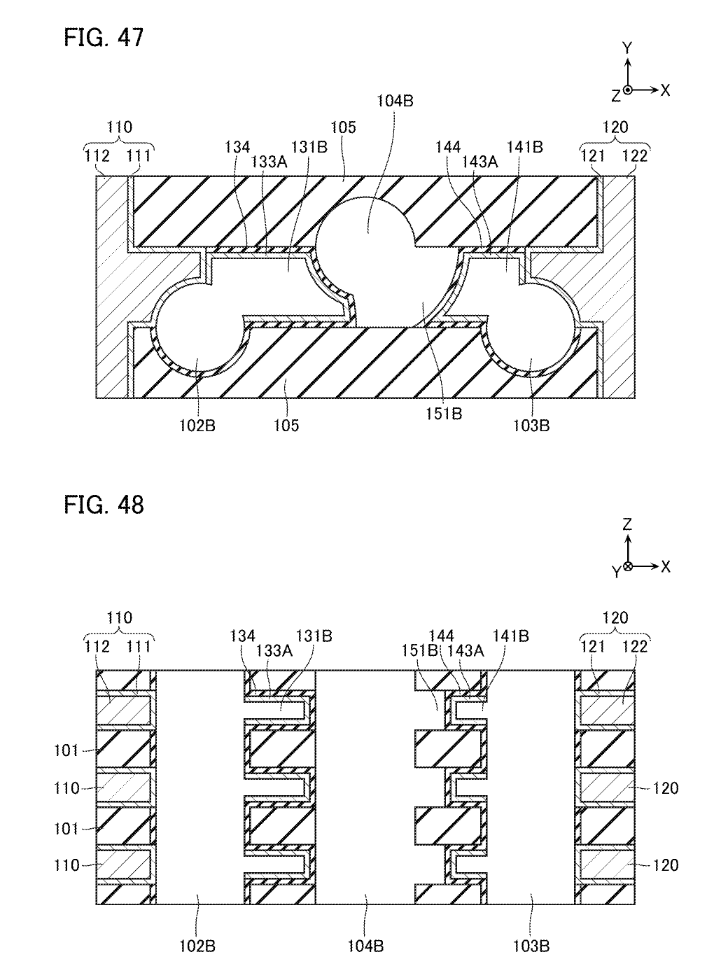

Next, for example, as illustrated in FIG. 47 and FIG. 48, the wirings 110 are formed inside the openings 110A, and the wirings 120 are formed inside the openings 120A. That is, in the openings 110A, the barrier conductive films 111 are formed on parts of the upper surfaces and parts of the lower surfaces of the insulating layers 101, parts of the side surfaces in the Y-direction and side surfaces on one side in the X-direction of the insulating members 105, parts of the outer peripheral surface of the sacrifice layer 102B, and the side surfaces of the conductive layers 133A on one side in the X-direction. In addition, the conductive films 112 are filled inside the openings 110A. Similarly, in the openings 120A, the barrier conductive films 121 are formed on parts of the upper surfaces and parts of the lower surfaces of the insulating layers 101, parts of the side surfaces in the Y-direction and side surfaces on the other side in the X-direction of the insulating members 105, parts of the outer peripheral surface of the sacrifice layer 103B, and the side surfaces of the conductive layers 143A on one side in the X-direction. In addition, the conductive films 122 are filled inside the openings 120A. This process is performed by, for example, CVD or the like.

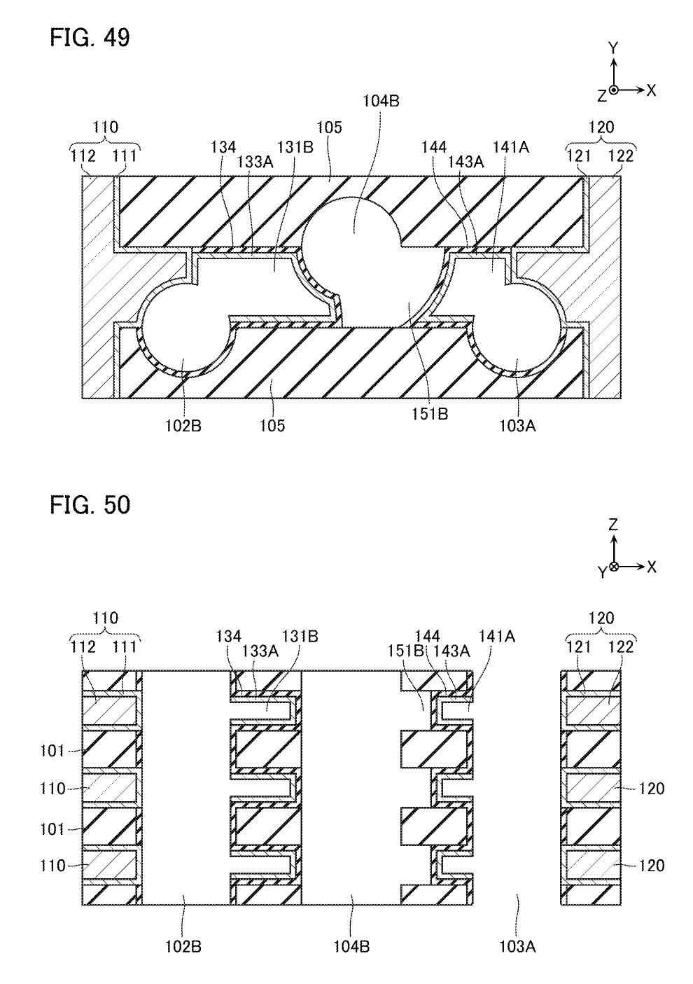

Next, for example, as illustrated in FIG. 49 and FIG. 50, the sacrifice layers 141B, 103B are removed. This process is performed by, for example, wet etching or the like.

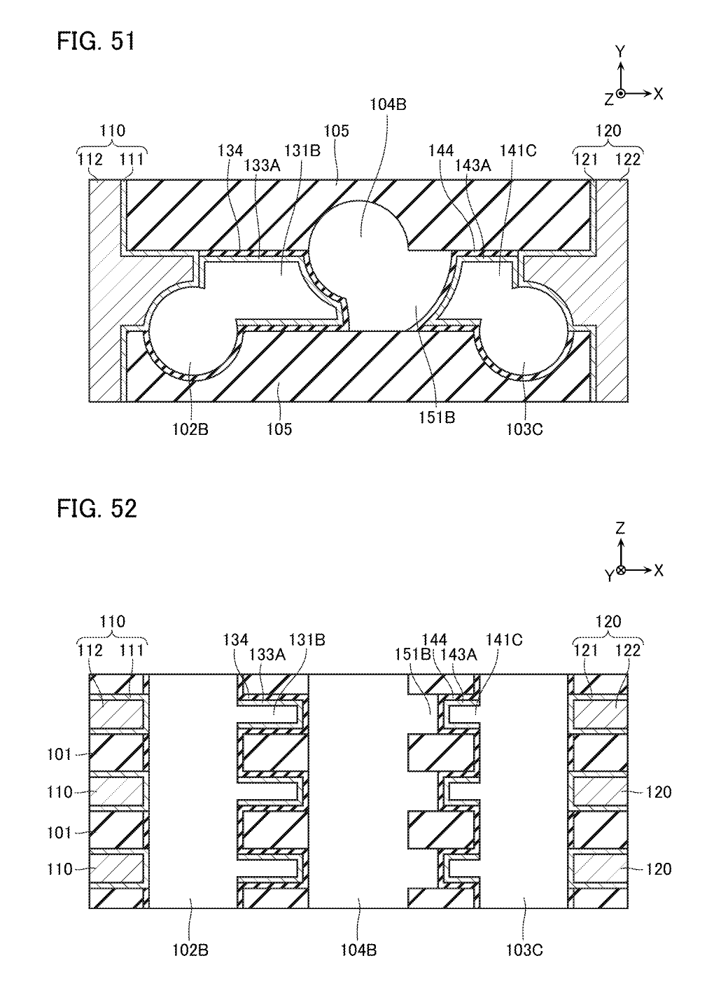

Next, for example, as illustrated in FIG. 51 and FIG. 52, the openings 141A are filled with sacrifice layers 141C of carbon (C) or the like, and the opening 103A is filled with a sacrifice layer 103C of carbon (C) or the like. This process is performed by, for example, CVD or the like. Although not illustrated, after this process is completed, an insulating layer or the like is formed at an upper portion of the sacrifice layer 103C.

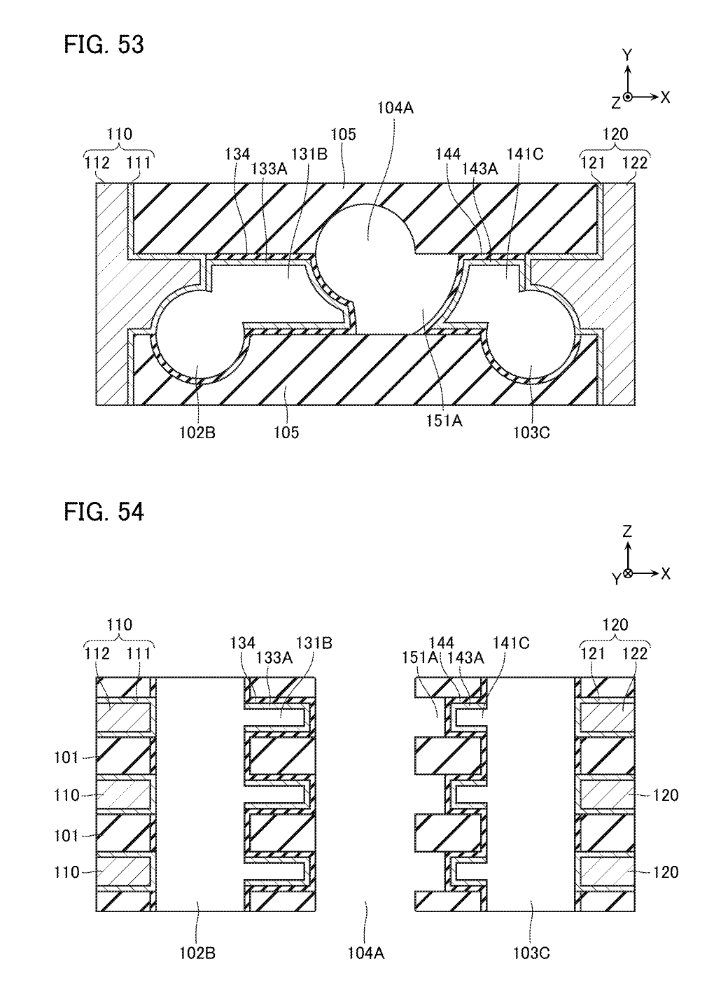

Next, for example, as illustrated in FIG. 53 and FIG. 54, the sacrifice layers 151B, 104B are removed. This process is performed by, for example, wet etching or the like.

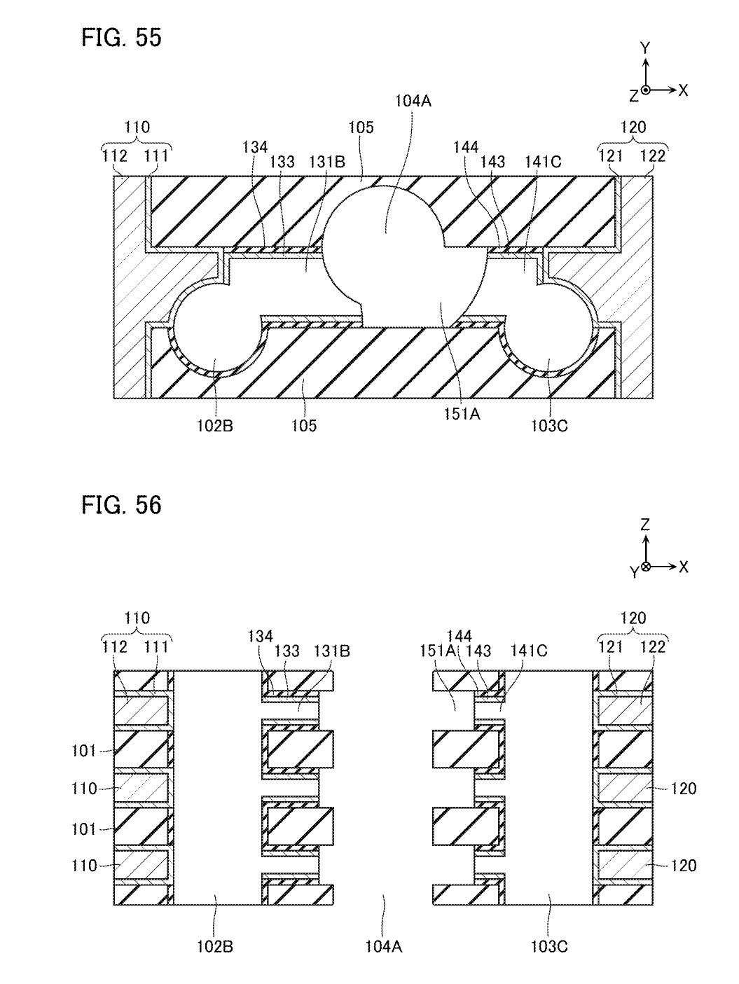

Next, for example, as illustrated in FIG. 55 and FIG. 56, parts of the insulating layers 134, 144 and parts of the conductive layers 133A, 143A are removed via the openings 151A, 104A to expose parts of the sacrifice layers 131B, 141C. This process is performed by, for example, wet etching or the like.

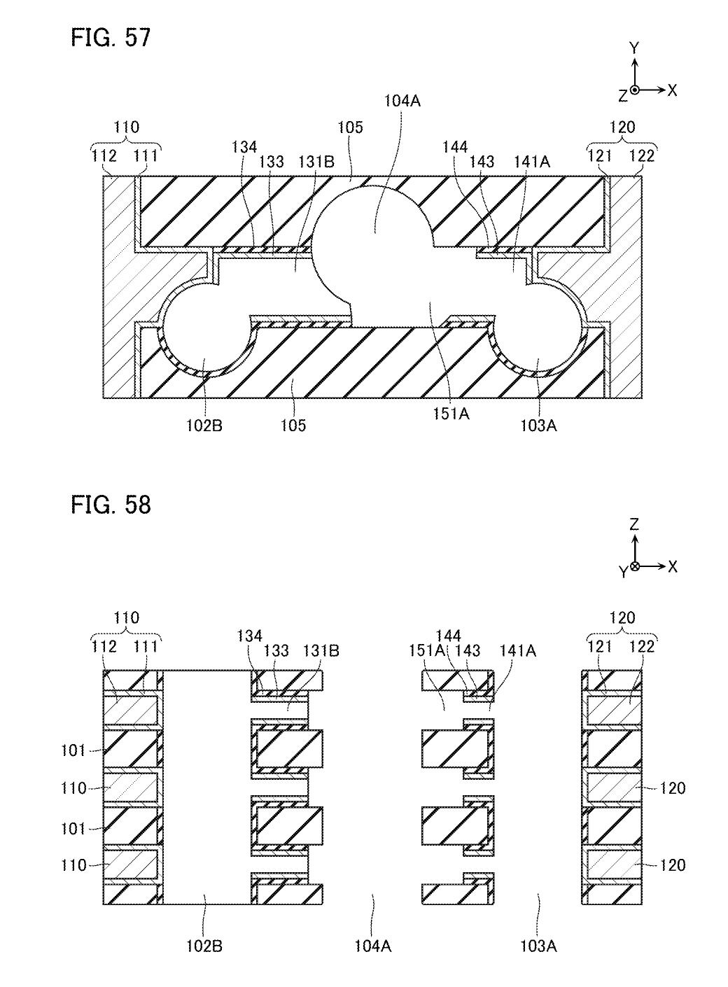

Next, for example, as illustrated in FIG. 57 and FIG. 58, the sacrifice layers 141C, 103C are removed. This process is performed by, for example, wet etching or the like.

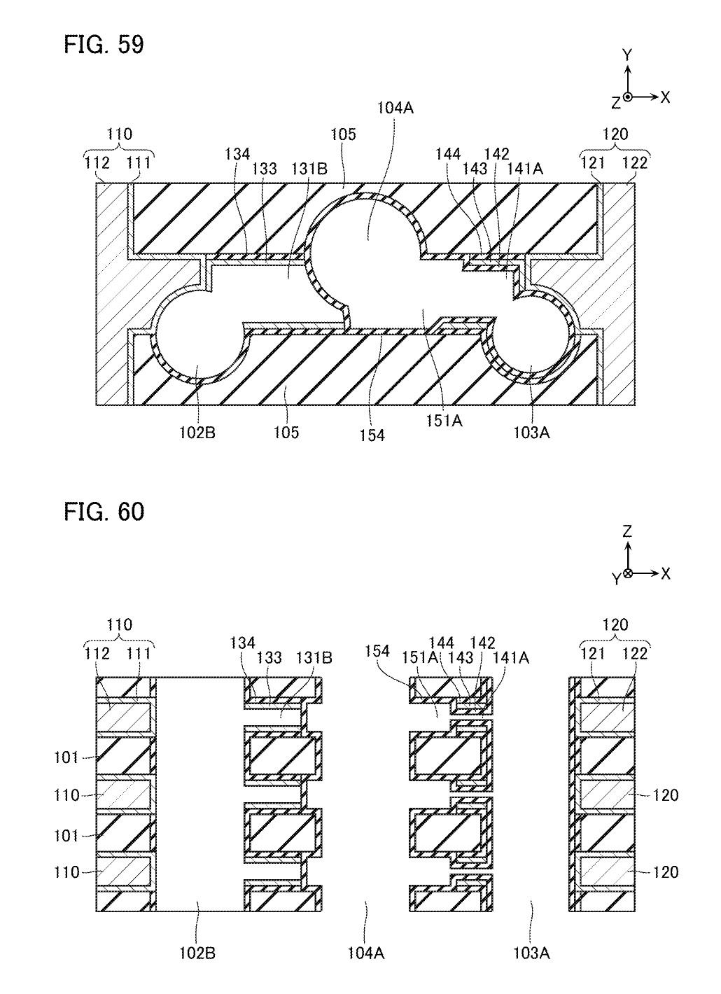

Next, for example, as illustrated in FIG. 59 and FIG. 60, the insulating layer 142 is formed inside the openings 141A, 103A. Similarly, the insulating layer 154 is formed inside the openings 151A, 104A. The insulating layer 142 is formed on exposed surfaces of the wirings 120 and the insulating layer 144 to the opening 103A, upper surfaces, lower surfaces, side surfaces in the Y-direction, and side surfaces in the X-direction of the conductive layers 143. The insulating layer 154 is formed on parts of the upper surfaces and parts of the lower surfaces of the insulating layers 101, exposed surfaces of the insulating layers 101 to the opening 104A, exposed surfaces of the conductive layers 133 and the sacrifice layer 131B to the opening 104A, and exposed surfaces of the insulating members 105 to the openings 151A, 104A. This process is performed by, for example, CVD or the like.

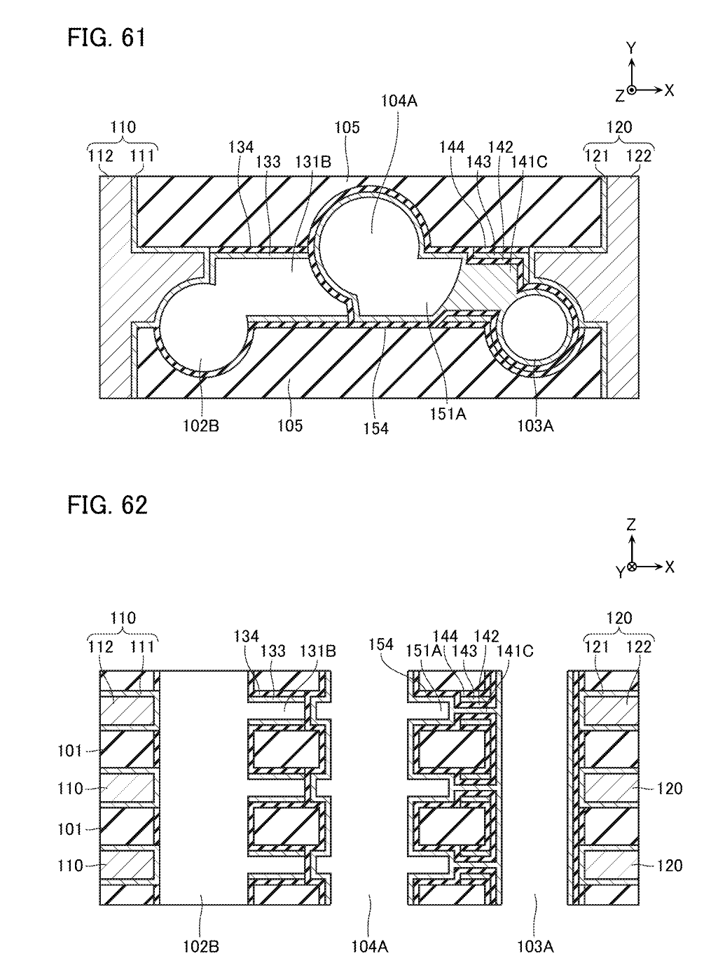

Next, for example, as illustrated in FIG. 61 and FIG. 62, a sacrifice layer 141C of titanium nitride (TiN) or the like is formed inside the openings 141A, 103A, 151A, 104A. The openings 141A are filled with the sacrifice layer 141C. The openings 103A, 151A, 104A are not filled with the sacrifice layer 141C. This process is performed by, for example, CVD or the like.

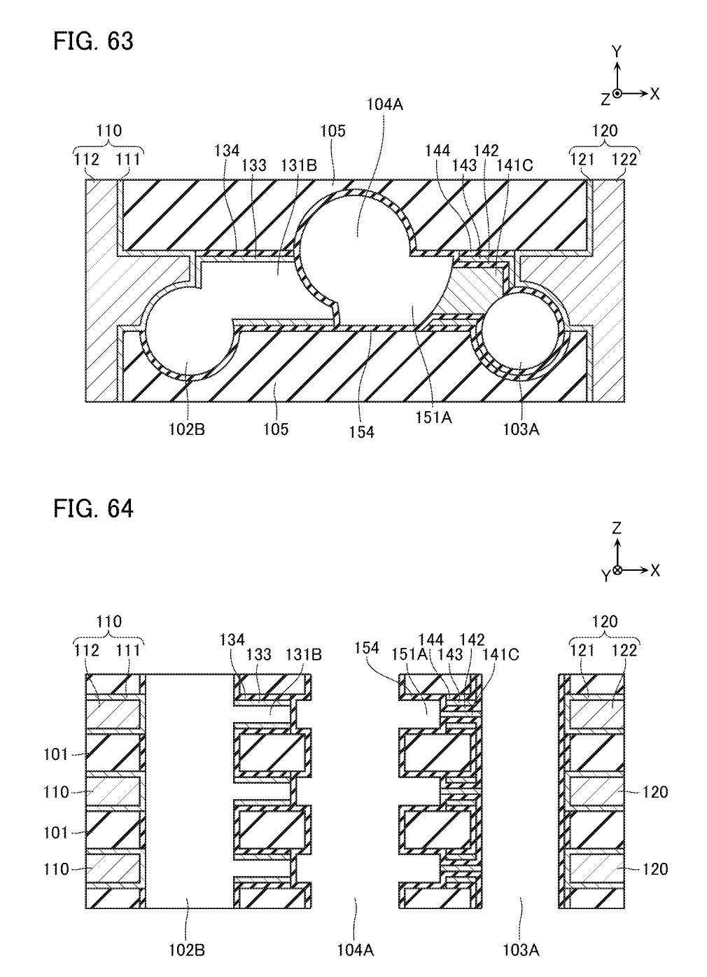

Next, for example, as illustrated in FIG. 63 and FIG. 64, a part of the sacrifice layer 141C that is formed in the opening 103A is removed to expose the insulating layer 142. In addition, a part of the sacrifice layer 141C that is formed in the openings 151A, 104A is removed to expose the insulating layer 154. This process is performed by, for example, wet etching or the like. Although not illustrated, after this process is completed, an insulating layer or the like is formed at an upper portion of the opening 103A.

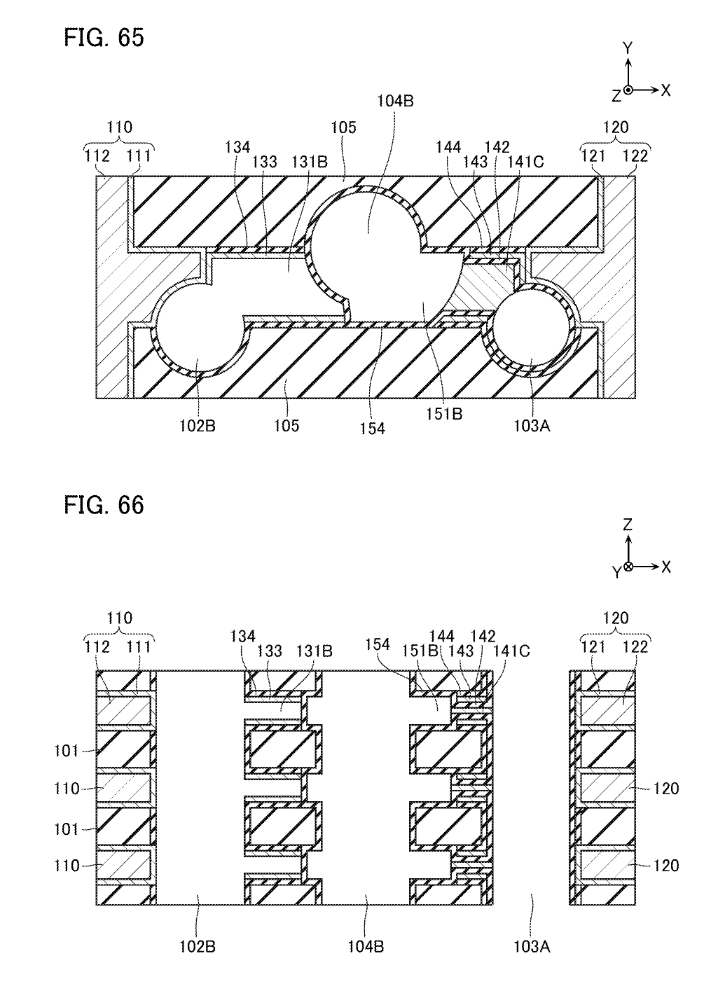

Next, for example, as illustrated in FIG. 65 and FIG. 66, sacrifice layers 151B, 104B of silicon (Si) or the like are formed inside the openings 151A, 104A, respectively. This process is performed by, for example, CVD or the like. Although not illustrated, after this process is completed, an insulating layer or the like is formed at an upper portion of the sacrifice layer 104B.

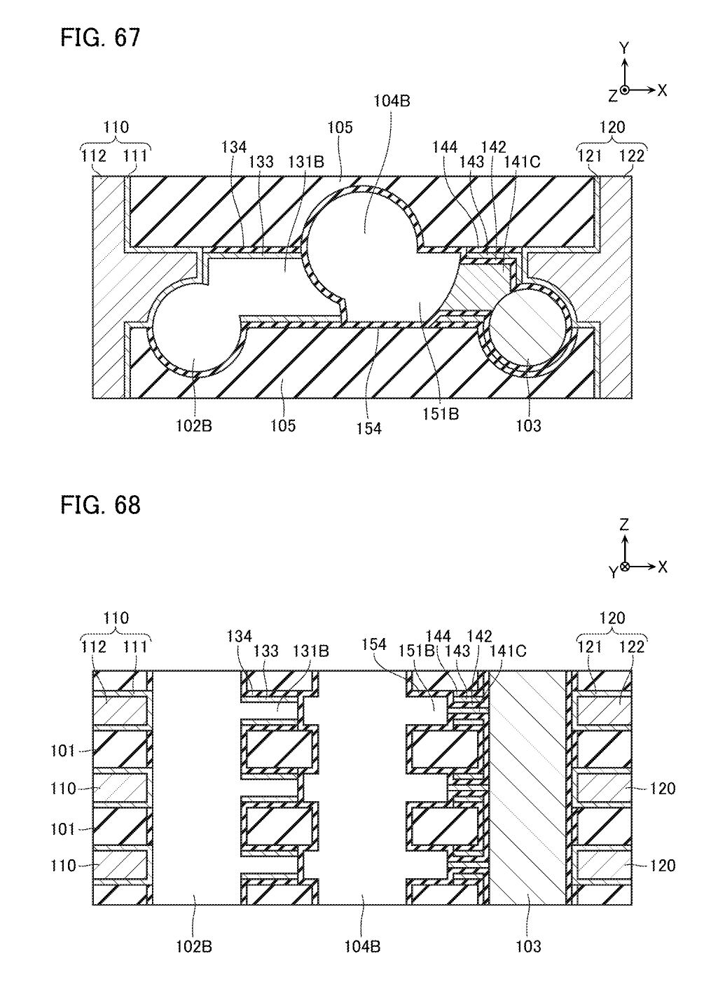

Next, for example, as illustrated in FIG. 67 and FIG. 68, the via-wiring 103 is formed inside the opening 103A. This process is performed by, for example, CVD or the like.

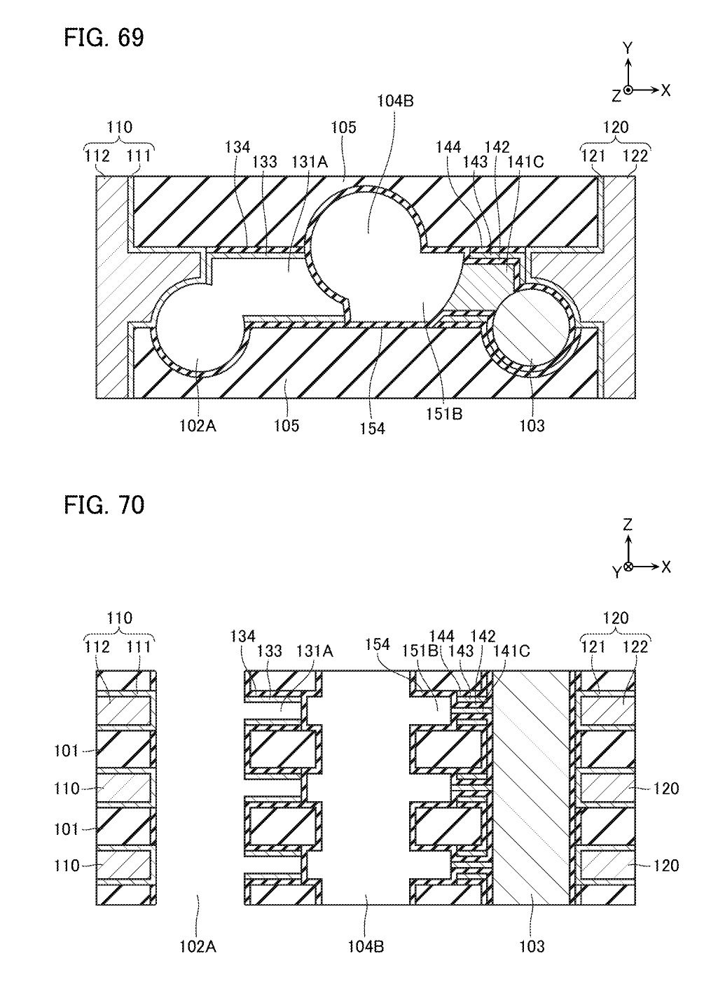

Next, for example, as illustrated in FIG. 69 and FIG. 70, the sacrifice layers 131B, 102B are removed. This process is performed by, for example, wet etching or the like.

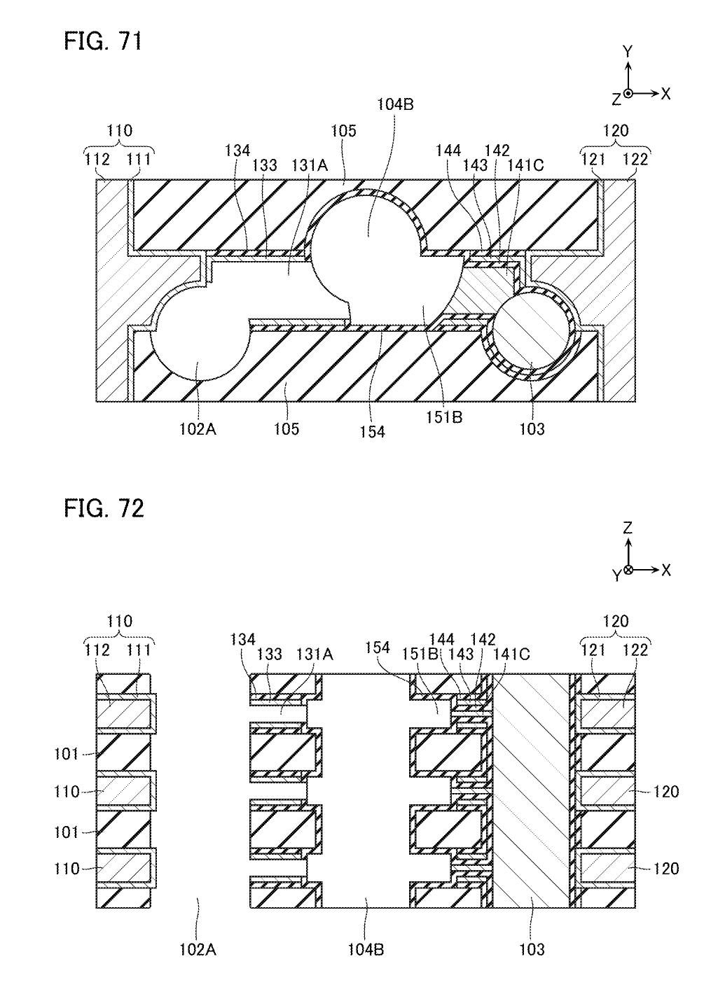

Next, for example, as illustrated in FIG. 71 and FIG. 72, parts of the insulating layer 154 are removed inside the openings 131A to expose parts of the outer peripheral surface of the sacrifice layer 104B. In addition, a part of the insulating layer 134 is removed inside the opening 102A to expose a part of the insulating members 105. This process is performed by, for example, wet etching or the like.

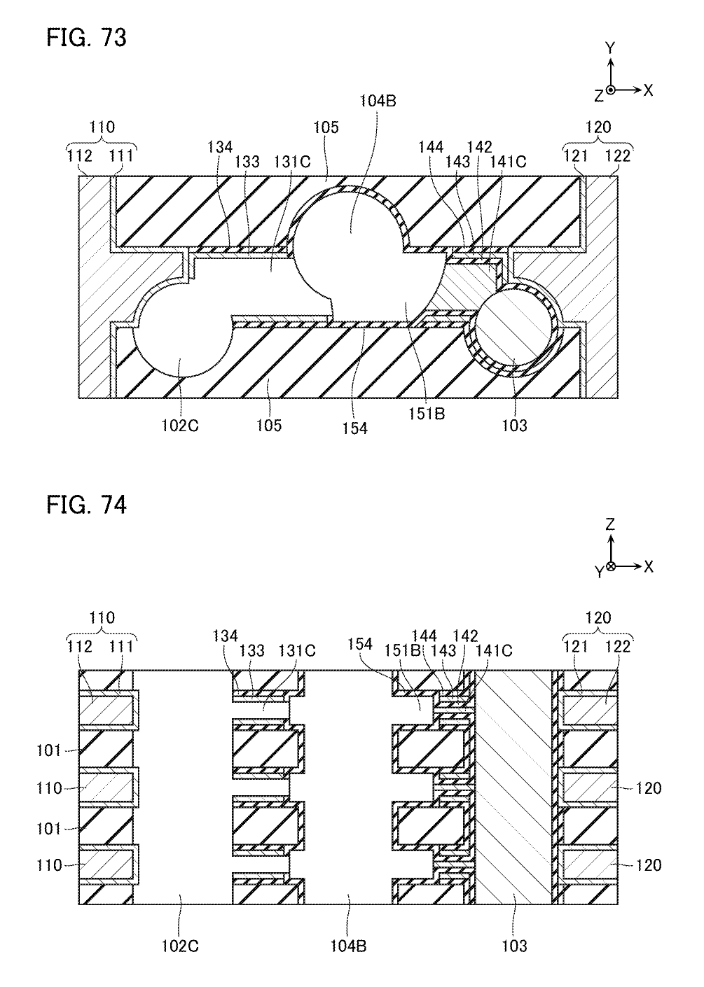

Next, for example, as illustrated in FIG. 73 and FIG. 74, sacrifice layers 131C, 102C of carbon (C) or the like are formed inside the openings 131A, 102A, respectively. This process is performed by, for example, CVD or the like. Although not illustrated, after this process is completed, an insulating layer or the like is formed at an upper portion of the sacrifice layer 102C.

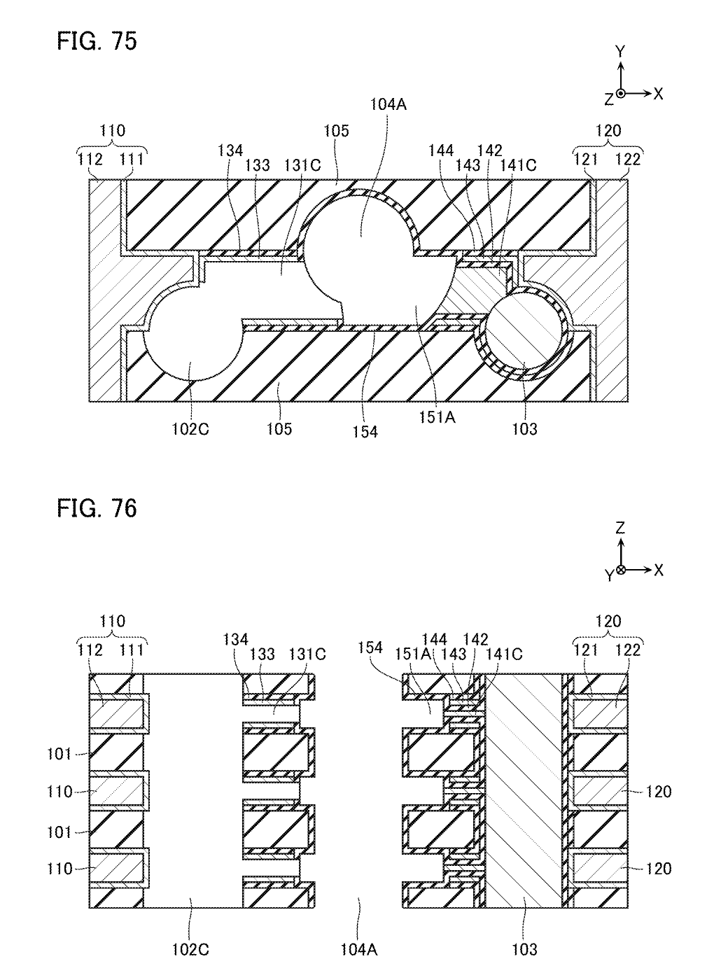

Next, for example, as illustrated in FIG. 75 and FIG. 76, the sacrifice layers 151B, 104B are removed. This process is performed by, for example, wet etching or the like.

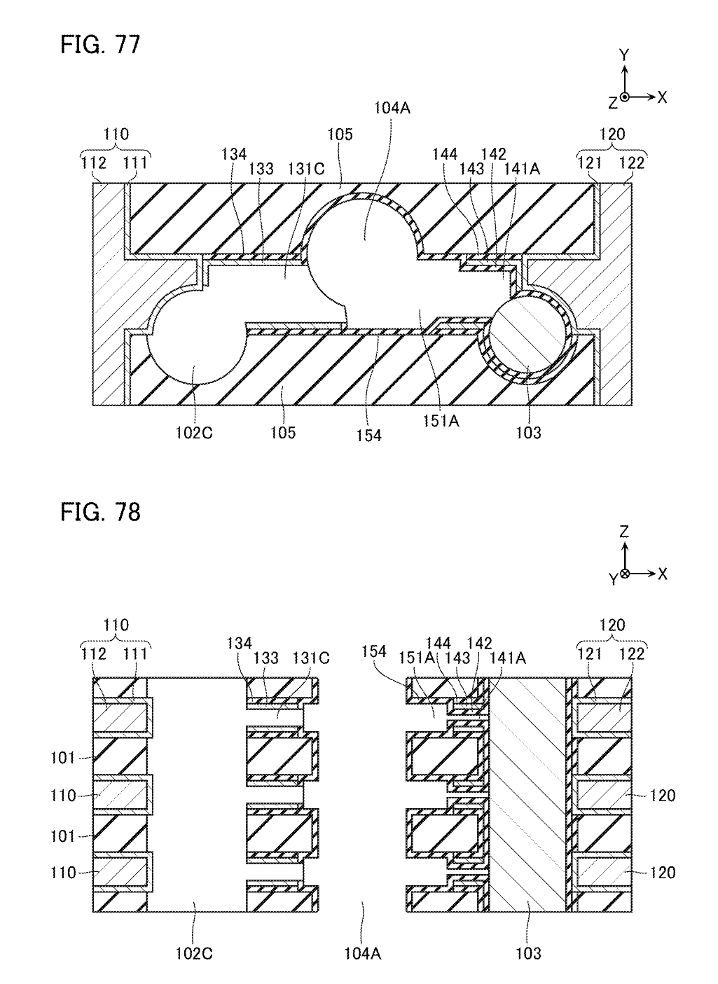

Next, for example, as illustrated in FIG. 77 and FIG. 78, the sacrifice layers 141C are removed. This process is performed by, for example, wet etching or the like.

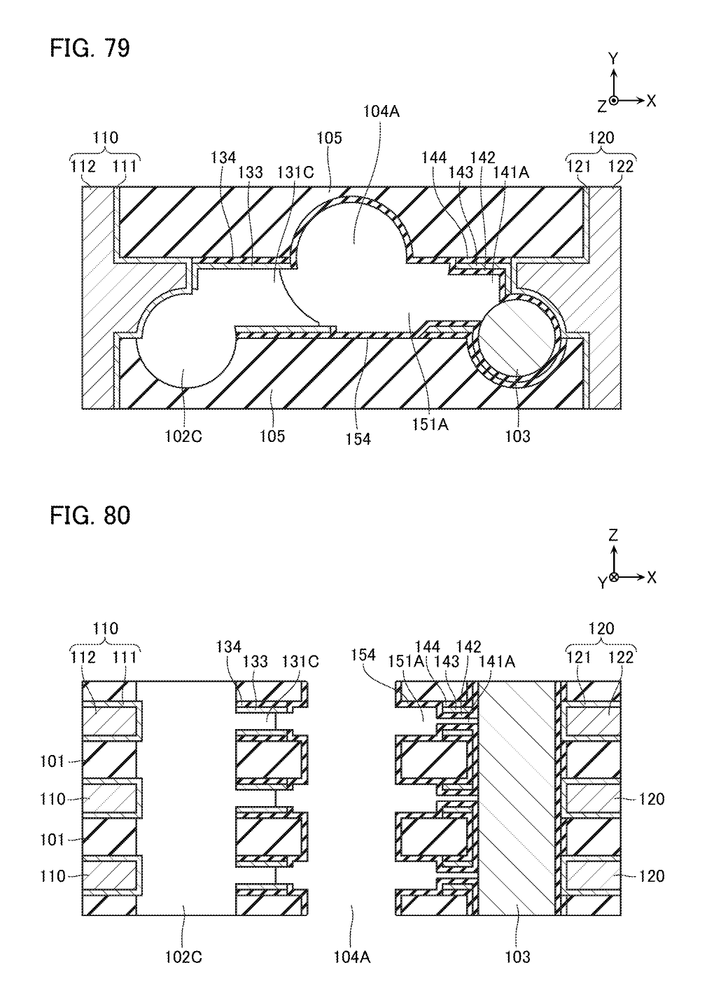

Next, for example, as illustrated in FIG. 79 and FIG. 80, parts of the sacrifice layer 131C are removed. This process is performed by, for example, wet etching or the like.

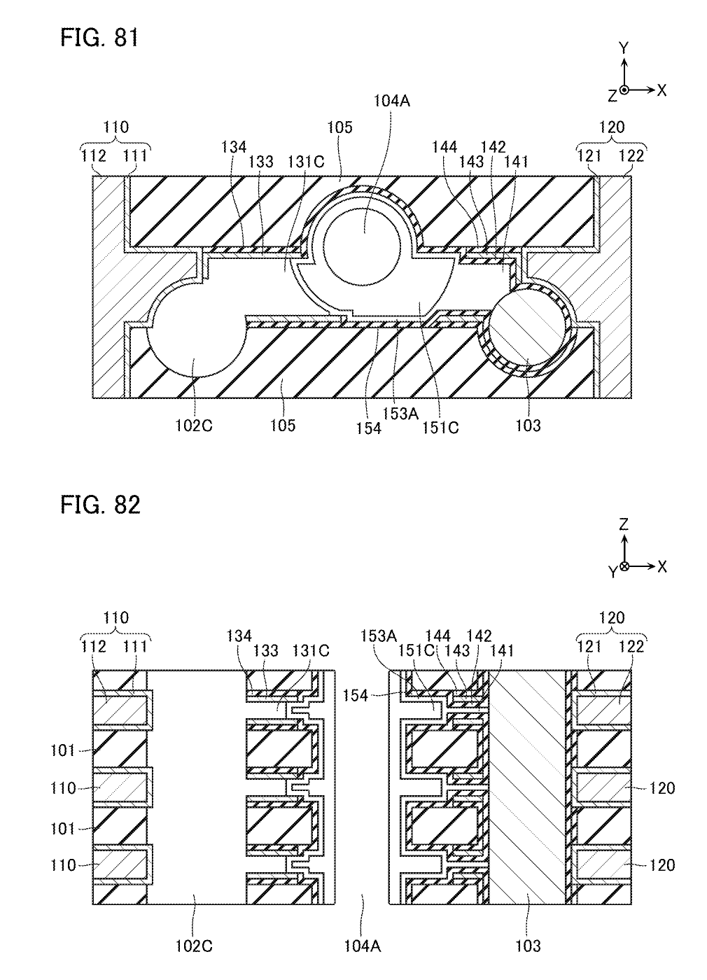

Next, for example, as illustrated in FIG. 81 and FIG. 82, the semiconductor layers 141 are formed inside the openings 141A. The openings 141A are filled with the semiconductor layers 141. In addition, a semiconductor layer 153A and a sacrifice layer 151C of carbon (C) or the like are formed inside the openings 151A, 104A. The openings 151A are filled with the semiconductor layer 153A and the sacrifice layer 151C. The opening 104A is not filled with the semiconductor layer 153A or the sacrifice layer 151C. This process is performed by, for example, CVD or the like.

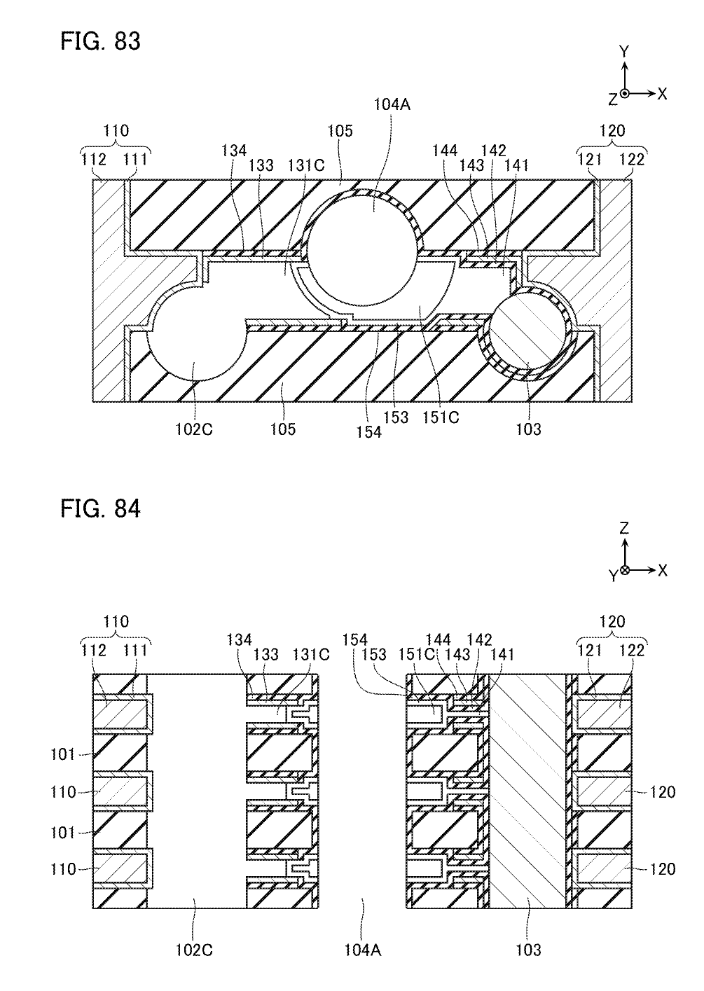

Next, as illustrated in FIG. 83 and FIG. 84, the sacrifice layer 151C is removed inside the opening 104A. This causes parts of an inner peripheral surface of the semiconductor layer 153A to be exposed to an inner peripheral surface of the opening 104A. Next, a part of the semiconductor layer 153A is removed to expose a part of the insulating layer 154 to an inside of the opening 104A. In this process, the semiconductor layer 153A is separated in the Z-direction, thus forming the plurality of semiconductor layers 153 arranged in the Z-direction. This process is performed by, for example, wet etching or the like.

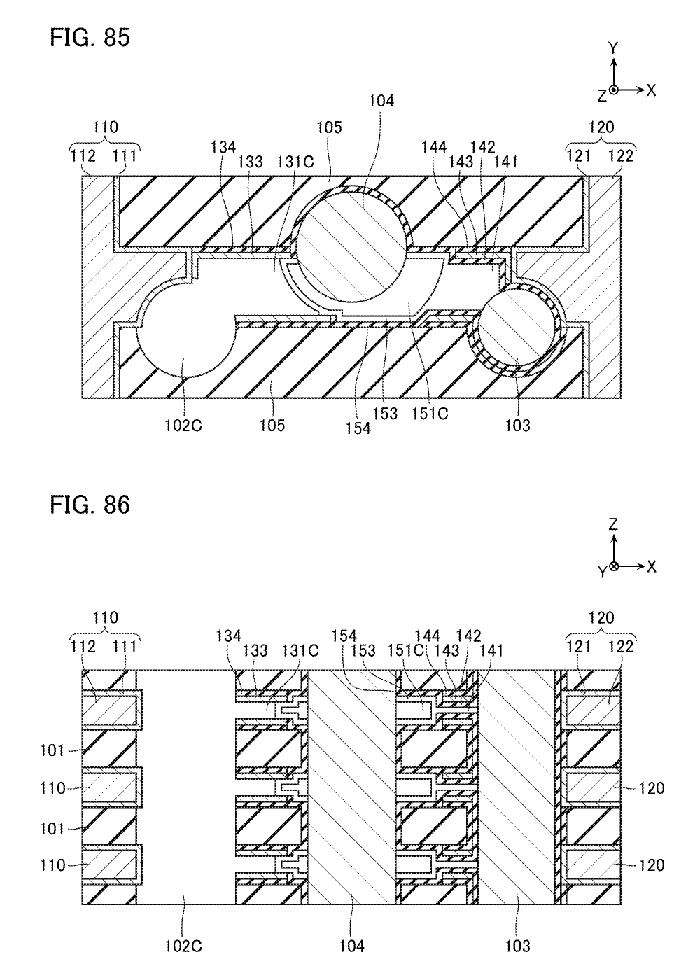

Next, as illustrated in FIG. 85 and FIG. 86, the via-wiring 104 is formed inside the opening 104A. This process is performed by, for example, CVD or the like.

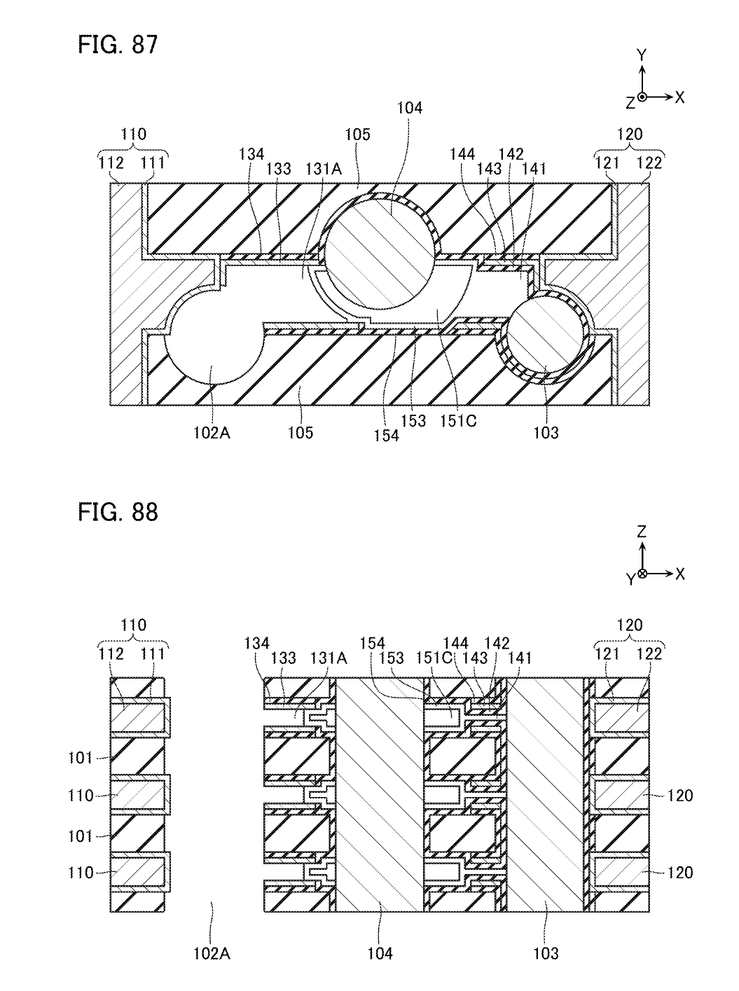

Next, as illustrated in FIG. 87 and FIG. 88, the sacrifice layers 131C, 102C are removed. This process is performed by, for example, wet etching or the like.

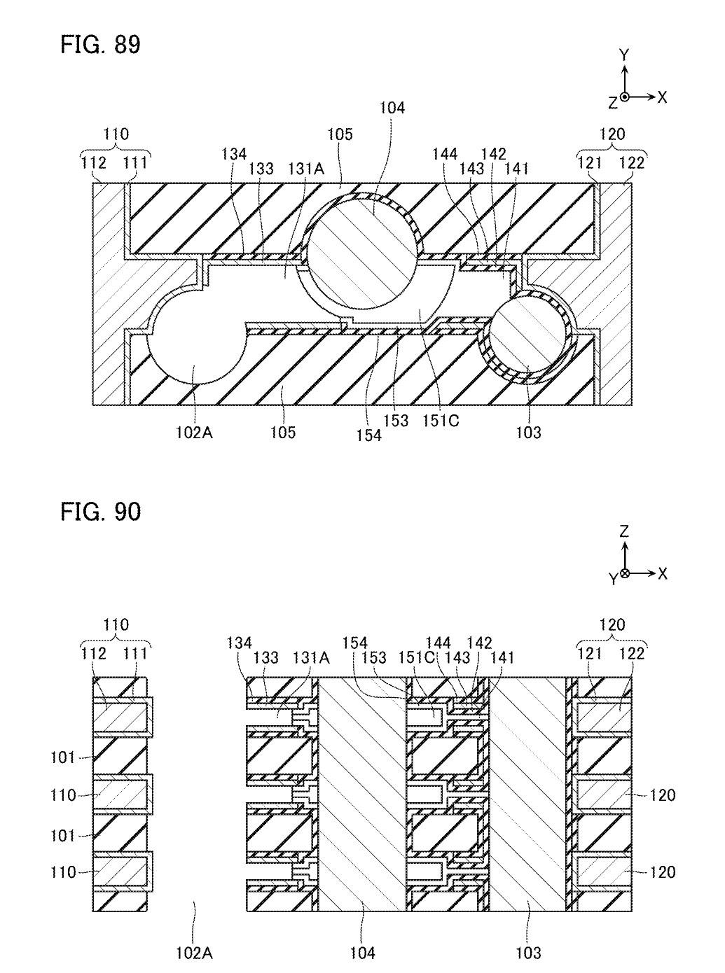

Next, as illustrated in FIG. 89 and FIG. 90, parts of the semiconductor layers 153 are removed via the openings 102A, 131A to expose side surfaces of the sacrifice layers 151C on one side in the X-direction. This process is performed by, for example, wet etching or the like.

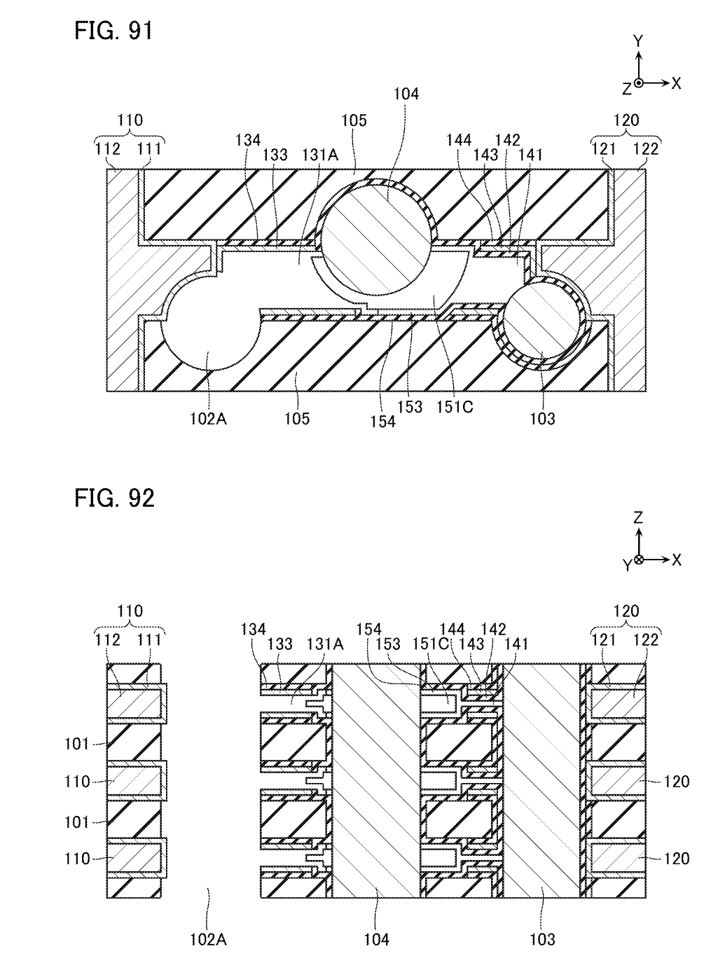

Next, as illustrated in FIG. 91 and FIG. 92, parts of the semiconductor layers 153 are further removed via the openings 102A, 131A. This process is performed by, for example, wet etching or the like.

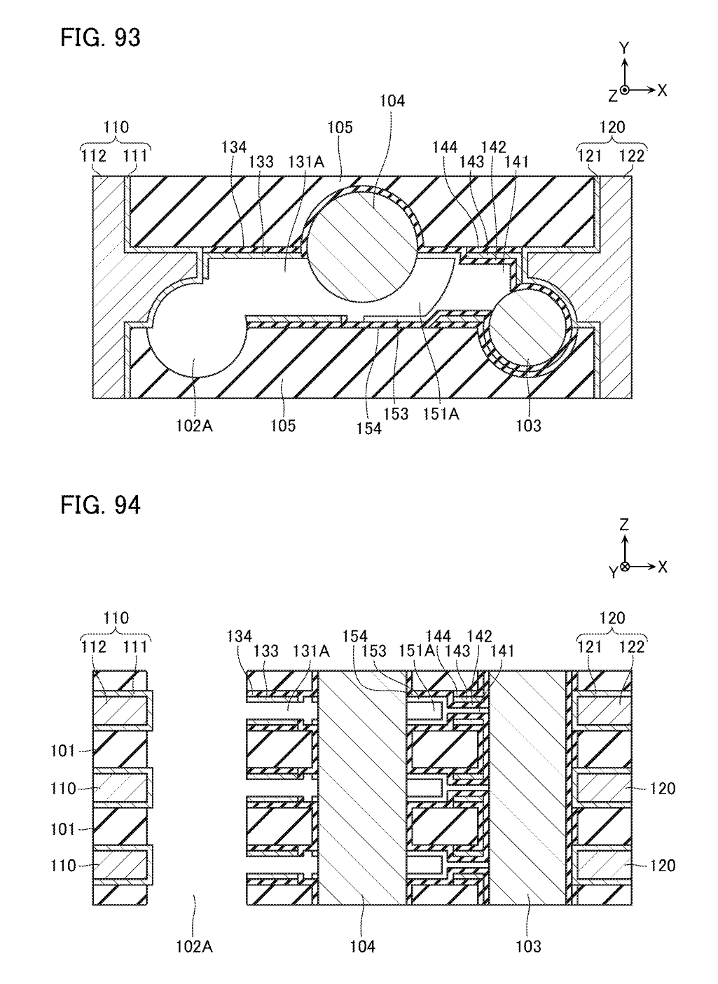

Next, as illustrated in FIG. 93 and FIG. 94, the sacrifice layers 151C are removed via the openings 102A, 131A. This process is performed by, for example, wet etching or the like.

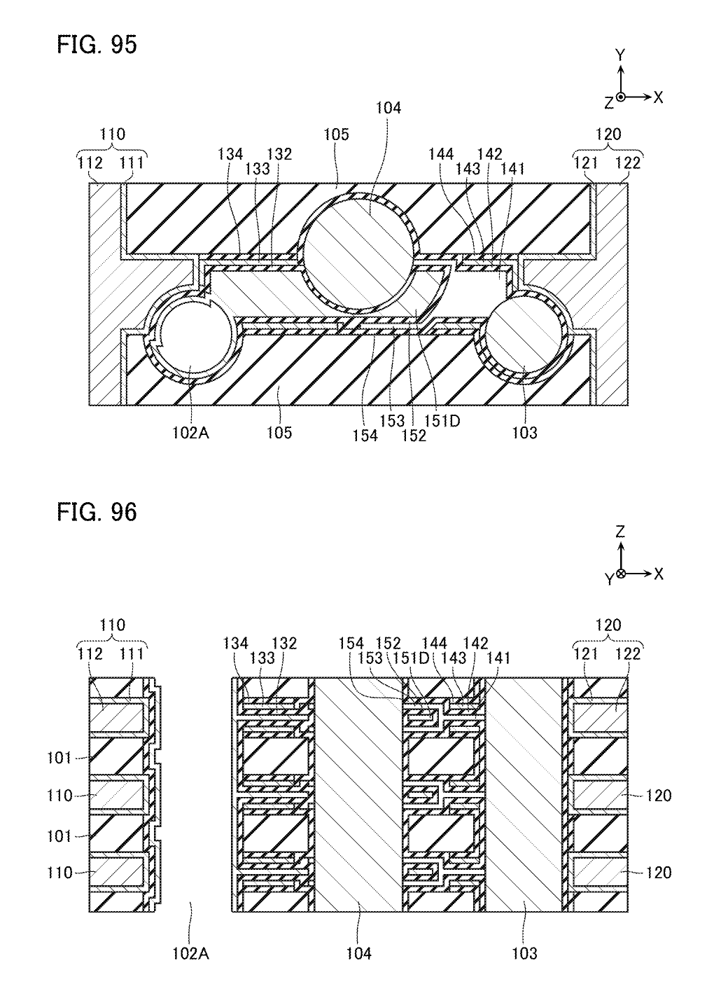

Next, as illustrated in FIG. 95 and FIG. 96, the insulating layers 152 are formed inside the openings 151A, and the insulating layer 132 is formed inside the openings 131A, 102A. Further, a conductive layer 151D is formed inside the openings 151A, 131A, 102A. The openings 151A, 131A are filled with the conductive layer 151D. The opening 102A is not filled with the conductive layer 151D. This process is performed by, for example, CVD or the like.

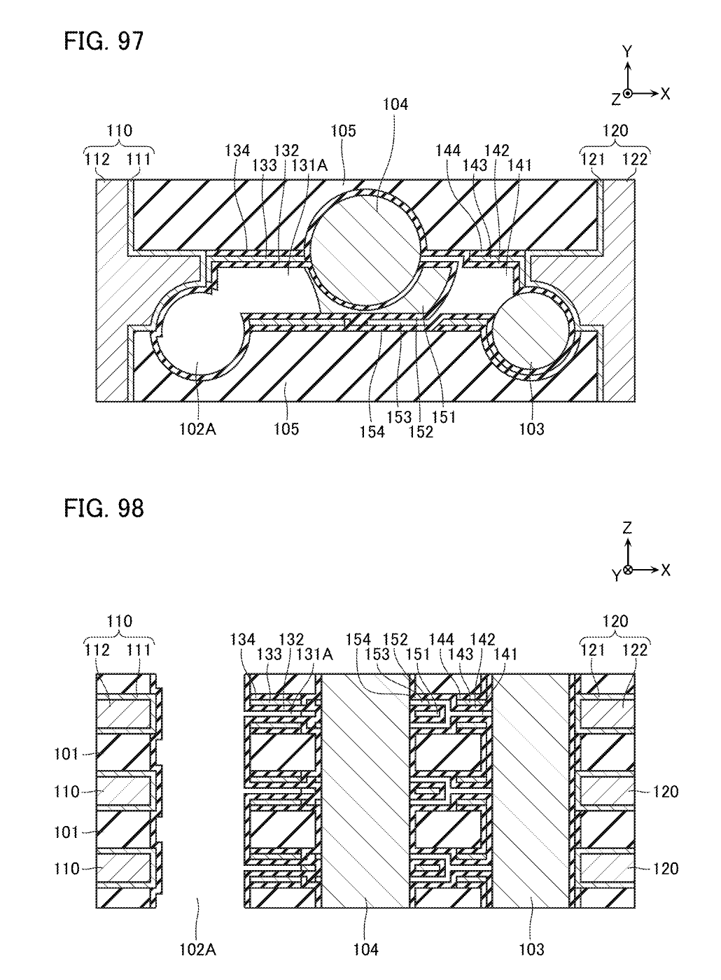

Next, as illustrated in FIG. 97 and FIG. 98, a part of the conductive layer 151D that is formed inside the openings 131A, 102A is removed. Thus, the conductive layers 151 are formed. This process is performed by, for example, wet etching or the like.

Then, as illustrated in FIG. 3 and FIG. 4, the semiconductor layers 131 are formed inside the openings 131A, and the via-wiring 102 is formed inside the opening 102A, thus forming the semiconductor memory device according to the first embodiment.

### Effects

The semiconductor memory device according to the embodiment includes the plurality of memory layers ML arranged in the Z-direction and the via-wirings 102, 103, 104 extending in the Z-direction. Each of the plurality of memory layers ML includes the transistor structures 130, 140, 150.

In such a configuration, only by increasing the number of insulating layers 101 and sacrifice layers MLA stacked in a stacking process (the process described with reference to FIG. 6), the number of memory layers ML included in the memory cell array MCA can be increased. Therefore, an increasing high integration can be relatively easily achieved.

However, in the configuration, when the distance between the memory layers ML decreases, the electrostatic capacitance between two conductive layers 151 adjacent to one another in the Z-direction increases. This possibly makes it difficult to execute writing and reading data appropriately, or increases the time required for writing and reading data.

Therefore, in the embodiment, as described with reference to FIG. 3, a part of the via-wiring 104 protrudes from the approximately rectangular region R_{R} between two insulating members 105 adjacent to one another in the Y-direction.

Such a structure allows decreasing the electrostatic capacitance between two conductive layers 151 adjacent to one another in the Z-direction, compared with, for example, a structure in which the via-wiring 104 does not protrude from the region R_{R}. This is because the conductive layer 151 surrounds the via-wiring 104 over the whole circumference in the structure in which the via-wiring 104 does not protrude from the region R_{R}, increasing the area of the conductive layer 151 in the XY plane by the amount.

In addition, in the embodiment, as described with reference to FIG. 3, not only a part of the via-wiring 104, but also parts of the via-wirings 102, 103 protrude from the region R_{R}.

Such a structure allows decreasing the areas of the transistor structures 130, 140 in the XY plane, compared with a structure in which the via-wirings 102, 103 do not protrude from the region R_{R}. This is because the semiconductor layer 131, the insulating layer 132, and the conductive layer 133 surround the via-wiring 102 over the whole circumference in the structure in which the via-wiring 102 does not protrude from the region R_{R}, increasing the area of the transistor structure 130 in the XY plane by the amount. Similarly, that is because the semiconductor layer 141, the insulating layer 142, and the conductive layer 143 surround the via-wiring 103 over the whole circumference in the structure in which the via-wiring 103 does not protrude from the region R_{R}, increasing the area of the transistor structure 140 in the XY plane by the amount.

Moreover, in the embodiment, in each memory layer ML, the semiconductor layer 153 covers the upper surface and the lower surface of the conductive layer 151 via the insulating layer 152. Such a structure allows the semiconductor layer 153 to block the electric field generated from the conductive layer 151, thereby reducing the electrostatic capacitance between two conductive layers 151 adjacent to one another in the Z-direction.

### Second Embodiment

In the first embodiment, as described with reference to FIG. 3, the via-wiring 104 and the via-wirings 102, 103 protrude inversely directions from the region R_{R} in the Y-direction. However, such a configuration is merely an example, and the arrangement of the via-wirings 102, 103, 104 can be adjusted as appropriate. For example, the via-wiring 104 and the via-wirings 102, 103 may protrude in the same direction from the region R_{R} in the Y-direction. The via-wiring 102 and the via-wiring 103 may protrude inversely from the region R_{R} in the Y-direction.

In addition, the positional relationship between the regions R_{R} and the via-wirings 102, 103, 104 may differ between two regions R_{R} adjacent to one another in the Y-direction. For example, both the via-wiring 104 corresponding to one region R_{R} and the via-wiring 104 corresponding to the other region R_{R} can be arranged between the two regions R_{R} adjacent to one another in the Y-direction. Furthermore, in such a case, configurations corresponding to the source lines SL can be realized by one via-wiring between the two regions R_{R} adjacent to one another in the Y-direction.

Such a configuration is exemplified below as a semiconductor memory device according to a second embodiment. In the following description, parts similar to those of the first embodiment are attached by the same reference numerals, and their descriptions are omitted.

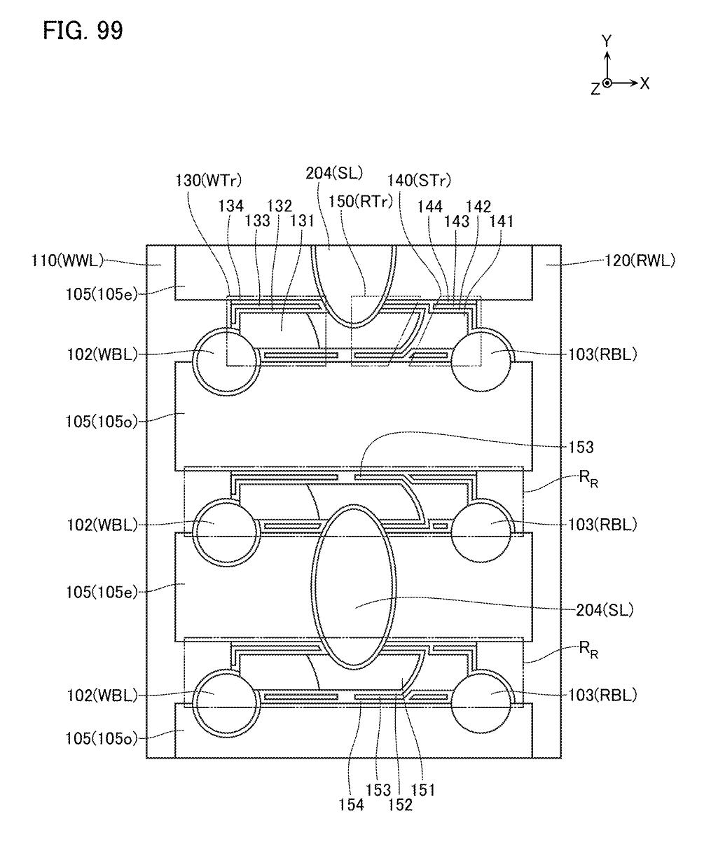

FIG. 99 is a schematic XY cross-sectional view illustrating a configuration of a part of the semiconductor memory device according to the second embodiment. The semiconductor memory device according to the second embodiment is configured basically similarly to that of the first embodiment.

However, in the semiconductor memory device according to the first embodiment, the via-wirings 104 corresponding to the source lines SL are disposed at positions in the Y-direction corresponding to all the insulating members 105. On the other hand, in the semiconductor memory device according to the second embodiment, via-wirings 204 corresponding to the source lines SL are disposed only at positions in the Y-direction corresponding to even-numbered insulating members 105 (insulating members 105e in FIG. 99) counting from the negative side in the Y-direction and not disposed at positions in the Y-direction corresponding to odd-numbered insulating members 105 (insulating members 105o in FIG. 99) counting from the negative side in the Y-direction.

The via-wiring 204 is configured basically similarly to the via-wiring 104. However, an end portion of the via-wiring 204 on one side in the Y-direction is disposed in the region R_{R} positioned on one side in the Y-direction with respect to the corresponding insulating member 105e, and an end portion of the via-wiring 204 on the other side in the Y-direction is disposed in the region R_{R} positioned on the other side in the Y-direction with respect to the corresponding insulating member 105e. In addition, the via-wiring 204 is connected to two semiconductor layers 153 corresponding to two regions R_{R} adjacent to one another in the Y-direction in each memory layer ML.

In the example of FIG. 99, the via-wirings 204 are disposed at the positions in the Y-direction corresponding to the insulating members 105e. Therefore, the insulating member 105e is separated in the X-direction into two parts via the via-wirings 204. Each of side surfaces of these two parts of the insulating members 105e on the positive side in the Y-direction has two linear parts extending in the X-direction and a curved part disposed between these two linear parts. This curved part is continuous with the two linear parts and formed along parts of the outer peripheral surfaces of the via-wirings 102, 103 (parts disposed outside the region R_{R}). Side surfaces of these two parts of the insulating members 105e on the negative side in the Y-direction are linearly formed and extend in the X-direction.

In the example of FIG. 99, the via-wirings 204 are not disposed at the positions in the Y-direction corresponding to the insulating members 105o. Therefore, the insulating member 105o is not separated in the X-direction. In addition, a side surface of the insulating member 105o on the negative side in the Y-direction is linearly formed and extends in the X-direction.

Such a configuration can also provide effects similar to those of the semiconductor memory device according to the first embodiment.

Further, with the configuration, widths of the insulating members 105e, 105o in the Y-direction can be reduced, thereby decreasing the area of the insulating members 105 in the XY plane.

The structure illustrated in FIG. 99 is merely an example, and the specific structure can be adjusted as appropriate. For example, the via-wirings 204 may be disposed at the positions in the Y-direction corresponding to the insulating members 105o, instead of the positions in the Y-direction corresponding to the insulating members 105e.

### Third Embodiment

Next, a semiconductor memory device according to a third embodiment is described. In the following description, parts similar to those of the second embodiment are attached by the same reference numerals, and their descriptions are omitted.

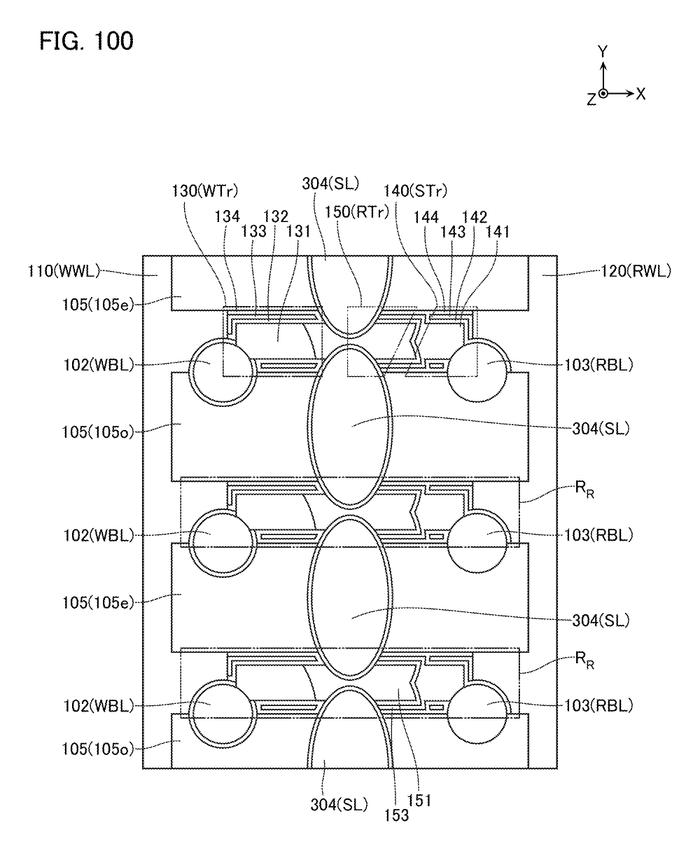

FIG. 100 is a schematic XY cross-sectional view illustrating a configuration of a part of the semiconductor memory device according to the third embodiment. The semiconductor memory device according to the third embodiment is configured basically similarly to that of the second embodiment. However, in the semiconductor memory device according to the third embodiment, via-wirings 304 corresponding to the source lines SL are disposed at positions in the Y-direction corresponding to all the insulating members 105.

On the XY cross-sectional surface exemplified in FIG. 100, each of both side surfaces of the conductive layer 151 in the Y-direction has two linear parts extending in the X-direction along a side surface of the insulating member 105 and a curved part disposed between these two parts. This curved part is continuous with the two linear parts and formed along a part of an outer peripheral surface of the via-wiring 304 (a part disposed inside the region R_{R}).

Such a configuration can also provide effects similar to those of the semiconductor memory device according to the second embodiment.

### Fourth Embodiment

Next, a semiconductor memory device according to a fourth embodiment is described. In the fourth embodiment, the select transistor STr (FIG. 1) includes a back gate electrode, and this back gate electrode is connected to the storage node SN. In the following description, parts similar to those of the first embodiment are attached by the same reference numerals, and their descriptions are omitted.

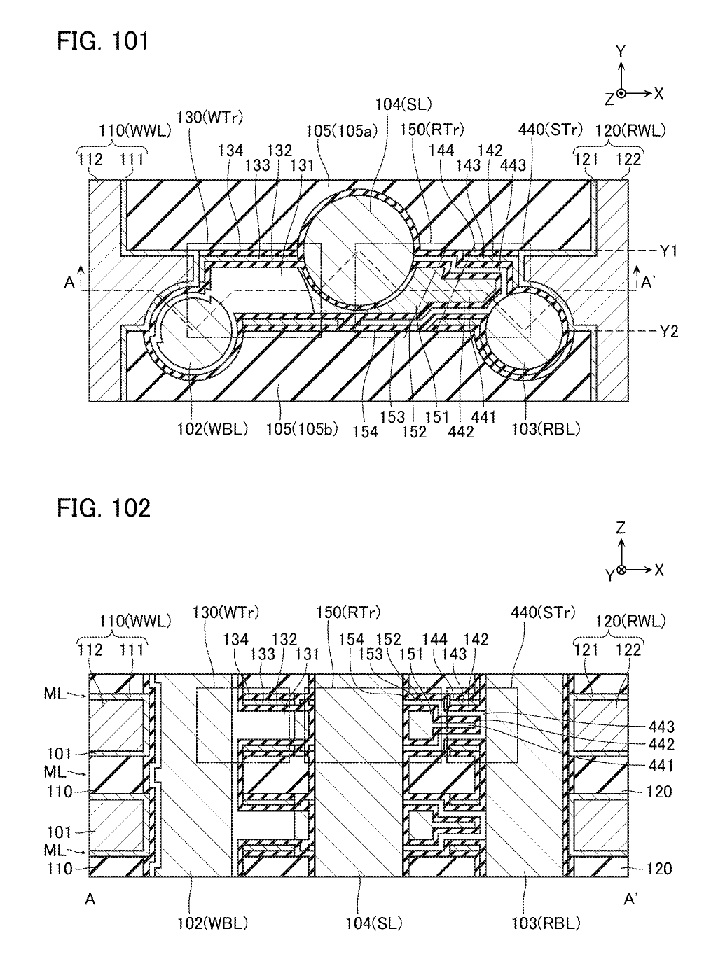

FIG. 101 is a schematic XY cross-sectional view illustrating a configuration of a part of the semiconductor memory device according to the fourth embodiment. FIG. 102 is a schematic cross-sectional view illustrating a configuration of a part of the semiconductor memory device, and illustrates a configuration of the structure illustrated in FIG. 101 taken along the line A-A' when viewed in the arrow direction.

The semiconductor memory device according to the fourth embodiment is configured basically similarly to that of the first embodiment. However, the semiconductor memory device according to the fourth embodiment includes transistor structures 440 instead of the transistor structures 140.

The transistor structure 440 includes a conductive layer 441, an insulating layer 442, a semiconductor layer 443, the insulating layer 142, the conductive layer 143, and the insulating layer 144. The conductive layer 441 extends in the X-direction in the above-described region R_{R}. The insulating layer 442 is disposed on an upper surface, a lower surface, both side surfaces in the Y-direction, and a side surface on one side (wiring 120 side) in the X-direction of the conductive layer 441. The semiconductor layer 443 is connected to a part of the outer peripheral surface of the via-wiring 103 and disposed on an upper surface, a lower surface, both side surfaces in the Y-direction, and a side surface on one side (wiring 120 side) in the X-direction of the insulating layer 442. The insulating layer 142 is disposed on an upper surface, a lower surface, both side surfaces in the Y-direction, and a side surface on one side (wiring 120 side) in the X-direction of the semiconductor layer 443. The conductive layer 143 is disposed on the upper surface, the lower surface, both side surfaces in the Y-direction, and the side surface on one side (wiring 120 side) in the X-direction of the insulating layer 142. The insulating layer 144 is disposed on the upper surface, the lower surface, and both side surfaces in the Y-direction of the conductive layer 143.

The conductive layer 441 functions as, for example, the back gate electrode of the select transistor STr (FIG. 1). The conductive layer 441 is continuous with the conductive layer 151 and contains a material similar to that of the conductive layer 151. The conductive layer 441 is formed simultaneously, for example, when the conductive layer 151 is formed.

The insulating layer 442 functions as, for example, a gate insulating film between the back gate electrode and the channel region of the select transistor STr (FIG. 1). The insulating layer 442 is continuous with the insulating layer 152 and contains a material similar to that of the insulating layer 152. The insulating layer 442 is formed simultaneously, for example, when the insulating layer 152 is formed.

The semiconductor layer 443 functions as, for example, the channel region of the select transistor STr (FIG. 1). The semiconductor layer 443 is configured similarly to the semiconductor layer 141, except for the points described above.

Such a configuration can also provide effects similar to those of the semiconductor memory device according to the first embodiment.

In the embodiment, a threshold voltage of a part of the plurality of select transistors STr (those included in the memory cells MC whose storage nodes SN are charged with the power supply voltage Vdd) is smaller than a threshold voltage of the other of the plurality of select transistors STr (those included in the memory cells MC whose storage nodes SN are charged with the ground voltage Vss). Here, for example, in the embodiment, it is considered that in the read operation, a voltage having a magnitude between these two threshold voltages is applied to the read word line RWL that is the target of the read operation. As a result, in the read operation, it is possible to set only the part of the select transistors STr to an ON state and set the other select transistors STr to an OFF state. Accordingly, a leakage current that may be generated between the read bit lines RBL and the source lines SL can be reduced appropriately in the read operation.

In addition, the conductive layer 441 of the semiconductor memory device according to the embodiment is continuous with the conductive layer 151, and the semiconductor layer 443 is opposed to the upper surface, the lower surface, both side surfaces in the Y-direction, and the side surface on one side (wiring 120 side) in the X-direction of the conductive layer 441. Here, for example, in the embodiment, it is considered that in the write operation, a fixed voltage, such as the ground voltage Vss, is applied to the read word line RWL. With such a method, the conductive layer 441 and the conductive layer 143 operate as capacitors, and therefore, the voltage of the storage node SN can be stabilized.

The semiconductor memory device according to the fourth embodiment may include the via-wirings 204, 304 (FIG. 99, FIG. 100) instead of the via-wirings 104. In such a case, the via-wirings 204 may be disposed only at the positions in the Y-direction corresponding to the insulating members 105e, similarly to the second embodiment, or may be disposed only at the positions in the Y-direction corresponding to the insulating members 105o. In addition, the via-wirings 304 may be disposed at the positions in the Y-direction corresponding to all the insulating members 105, similarly to the third embodiment.

### Fifth Embodiment

In the first embodiment, in the transistor structure 130 corresponding to the write transistor WTr, the conductive layer 133 functioning as the gate electrode is opposed to the upper surface, the lower surface, and both side surfaces in the Y-direction of the semiconductor layer 131 functioning as the channel region.

Similarly, in the transistor structure 140 corresponding to the select transistor STr, the conductive layer 143 functioning as the gate electrode is opposed to the upper surface, the lower surface, and both side surfaces in the Y-direction of the semiconductor layer 141 functioning as the channel region.

Meanwhile, in the transistor structure 150 corresponding to the read transistor RTr, the semiconductor layer 153 functioning as the channel region is opposed to the upper surface, the lower surface, and both side surfaces in the Y-direction of the conductive layer 151 functioning as the gate electrode.

However, such a configuration is adjustable as appropriate. For example, in a transistor structure corresponding to at least one of the write transistor WTr or the select transistor STr, a semiconductor layer functioning as the channel region may be opposed to an upper surface, a lower surface, and both side surfaces in the Y-direction of a conductive layer functioning as the gate electrode. Further, in a transistor structure corresponding to the read transistor RTr, a conductive layer functioning as the gate electrode may be opposed to an upper surface, a lower surface, and both side surfaces in the Y-direction of a semiconductor layer functioning as the channel region.

As a semiconductor memory device according to a fifth embodiment, an example in which in the transistor structure corresponding to the read transistor RTr, the conductive layer functioning as the gate electrode is opposed to the upper surface, the lower surface, and both side surfaces in the Y-direction of the semiconductor layer functioning as the channel region is described below. In the following description, parts similar to those of the first embodiment are attached by the same reference numerals, and their descriptions are omitted.

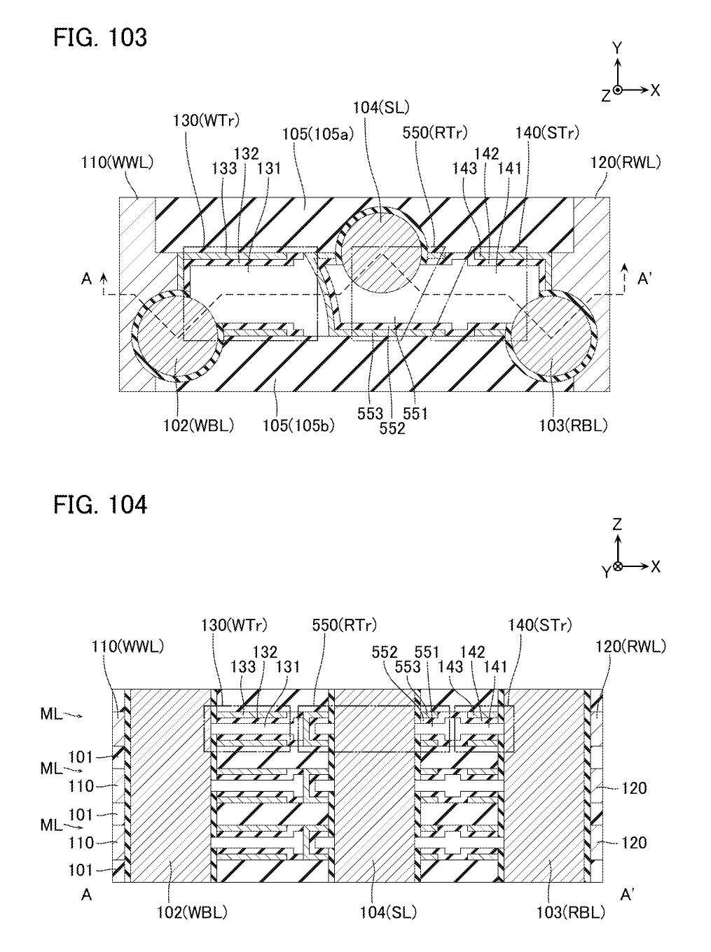

FIG. 103 is a schematic XY cross-sectional view illustrating a configuration of a part of the semiconductor memory device according to the fifth embodiment. FIG. 104 is a schematic cross-sectional view illustrating a configuration of a part of the semiconductor memory device, and illustrates a configuration of the structure illustrated in FIG. 103 taken along the line A-A' when viewed in the arrow direction.

The semiconductor memory device according to the fifth embodiment is configured basically similarly to that of the first embodiment. However, the semiconductor memory device according to the fifth embodiment includes transistor structures 550 instead of the transistor structures 150.

The transistor structure 550 includes a semiconductor layer 551, an insulating layer 552, and a conductive layer 553. The semiconductor layer 551 is connected to a part of the outer peripheral surface of the via-wiring 104 and extends in the X-direction in the region R_{R}. The insulating layer 552 is disposed on an upper surface, a lower surface, both side surfaces in the Y-direction, and a side surface on one side (wiring 110 side) in the X-direction of the semiconductor layer 551. The conductive layer 553 is disposed on an upper surface, a lower surface, both side surfaces in the Y-direction, and a side surface on one side (wiring 110 side) in the X-direction of the insulating layer 552.

On an XY cross-sectional surface exemplified in FIG. 103, the side surface of the semiconductor layer 551 on one side (wiring 110 side) in the X-direction may be formed along a circle with the center position of the via-wiring 102 as its center. In addition, the side surfaces of the semiconductor layer 551, the insulating layer 552, and the conductive layer 553 on one side in the Y-direction may be linearly formed along the side surface of the insulating member 105. Further, the side surface of the semiconductor layer 551 on the other side in the Y-direction may have two linear parts extending in the X-direction and a curved part disposed between these two parts. This curved part may be continuous with the two linear parts and formed along a part of the outer peripheral surface of the via-wiring 104 (a part disposed inside the region R_{R}).

The semiconductor layer 551 functions as, for example, the channel region of the read transistor RTr (FIG. 1). The semiconductor layer 551 is continuous with the semiconductor layer 141 and contains a material similar to that of the semiconductor layer 141. The semiconductor layer 551 is formed simultaneously, for example, when the semiconductor layer 141 is formed.

The insulating layer 552 functions as, for example, the gate insulating film of the read transistor RTr (FIG. 1). The insulating layer 552 is continuous with the insulating layer 142 and contains a material similar to that of the insulating layer 142. The insulating layer 552 is formed simultaneously, for example, when the insulating layer 142 is formed.

The conductive layer 553 functions as, for example, the storage node SN (FIG. 1) and the gate electrode of the read transistor RTr (FIG. 1). The conductive layer 553 contains a material similar to that of the conductive layer 143. The conductive layer 553 is formed simultaneously, for example, when the conductive layer 143 is formed. A side surface of the conductive layer 553 on one side (wiring 110 side) in the X-direction is connected to the semiconductor layer 131.

In such a configuration, similarly to the first embodiment, a part of the via-wiring 104 protrudes from the approximately rectangular region R_{R} between two insulating members 105 adjacent to one another in the Y-direction. Therefore, the electrostatic capacitance between two conductive layers 553 adjacent to one another in the Z-direction can be decreased compared with a structure in which the via-wiring 104 does not protrude from the region R_{R}.

In addition, in the configuration, similarly to the first embodiment, not only a part of the via-wiring 104, but also parts of the via-wirings 102, 103 protrude from the region R_{R}. Therefore, the areas of the transistor structures 130, 140 in the XY plane can be decreased compared with a structure in which the via-wirings 102, 103 do not protrude from the region R_{R}.

The transistor structures 130, 140 according to the embodiment may include the insulating layers 134, 144, similarly to the transistor structures 130, 140 according to the first embodiment.

The semiconductor memory device according to the fifth embodiment may also include the via-wirings 204, 304 (FIG. 99, FIG. 100) instead of the via-wirings 104. In such a case, the via-wirings 204 may be disposed only at the positions in the Y-direction corresponding to the insulating members 105e, similarly to the second embodiment, or may be disposed only at the positions in the Y-direction corresponding to the insulating members 105o. In addition, the via-wirings 304 may be disposed at the positions in the Y-direction corresponding to all the insulating members 105, similarly to the third embodiment.

### Sixth Embodiment

Next, a semiconductor memory device according to a sixth embodiment is described. In the sixth embodiment, the select transistor STr (FIG. 1) includes a floating gate electrode, and this floating gate electrode is connected to the storage node SN. In the following description, parts similar to those of the fifth embodiment are attached by the same reference numerals, and their descriptions are omitted.

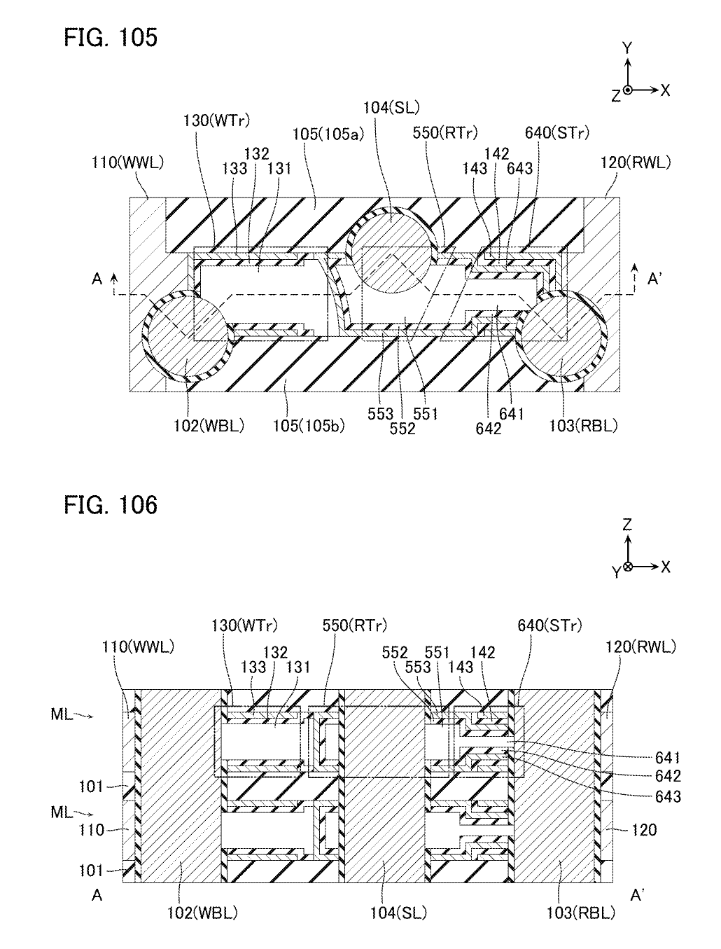

FIG. 105 is a schematic XY cross-sectional view illustrating a configuration of a part of the semiconductor memory device according to the sixth embodiment. FIG. 106 is a schematic cross-sectional view illustrating a configuration of a part of the semiconductor memory device, and illustrates a configuration of the structure illustrated in FIG. 105 taken along the line A-A' when viewed in the arrow direction.

The semiconductor memory device according to the sixth embodiment is configured basically similarly to that of the fifth embodiment. However, the semiconductor memory device according to the sixth embodiment includes transistor structures 640 instead of the transistor structures 140.

The transistor structure 640 includes a semiconductor layer 641, an insulating layer 642, a conductive layer 643, the insulating layer 142, and the conductive layer 143. The semiconductor layer 641 is connected to a part of the outer peripheral surface of the via-wiring 103 and extends in the X-direction in the above-described region R_{R}. The insulating layer 642 is disposed on an upper surface, a lower surface, both side surfaces in the Y-direction, and a side surface on one side (wiring 120 side) in the X-direction of the semiconductor layer 641. The conductive layer 643 is disposed on an upper surface, a lower surface, both side surfaces in the Y-direction, and a side surface on one side (wiring 120 side) in the X-direction of the insulating layer 642. The insulating layer 142 is disposed on an upper surface, a lower surface, both side surfaces in the Y-direction, and a side surface on one side (wiring 120 side) in the X-direction of the conductive layer 643. The conductive layer 143 is disposed on the upper surface, the lower surface, both side surfaces in the Y-direction, and the side surface on one side (wiring 120 side) in the X-direction of the insulating layer 142.

The semiconductor layer 641 functions as, for example, the channel region of the select transistor STr (FIG. 1). The semiconductor layer 641 is continuous with the semiconductor layer 551 and contains a material similar to that of the semiconductor layer 551. The semiconductor layer 641 is formed simultaneously, for example, when the semiconductor layer 551 is formed.

The insulating layer 642 functions as, for example, a gate insulating film between the floating gate electrode and the channel region of the select transistor STr (FIG. 1). The insulating layer 642 is continuous with the insulating layer 552 and contains a material similar to that of the insulating layer 552. The insulating layer 642 is formed simultaneously, for example, when the insulating layer 552 is formed.

The conductive layer 643 functions as, for example, the floating gate electrode of the select transistor STr (FIG. 1). The conductive layer 643 is continuous with the conductive layer 553 and contains a material similar to that of the conductive layer 553. The conductive layer 643 is formed simultaneously, for example, when the conductive layer 553 is formed.

Such a configuration can also provide effects similar to those of the semiconductor memory device according to the fifth embodiment.

In addition, with the embodiment, similarly to the fourth embodiment, it is considered that in the read operation, a voltage having a magnitude between the above-described two threshold voltages is applied to the read word line RWL that is the target of the read operation. Accordingly, similarly to the fourth embodiment, the leakage current that may be generated between the read bit lines RBL and the source lines SL can be reduced appropriately in the read operation.

Further, with the embodiment, similarly to the fourth embodiment, it is considered that in the write operation, a fixed voltage, such as the ground voltage Vss, is applied to the read word line RWL. As a result, the voltage of the storage node SN can be stabilized.

The transistor structure 130 according to the embodiment may include the insulating layer 144, similarly to the transistor structure 130 according to the first embodiment.

In addition, the semiconductor memory device according to the sixth embodiment may include the via-wirings 204, 304 (FIG. 99, FIG. 100) instead of the via-wirings 104. In such a case, the via-wirings 204 may be disposed only at the positions in the Y-direction corresponding to the insulating members 105e, similarly to the second embodiment, or may be disposed only at the positions in the Y-direction corresponding to the insulating members 105o. In addition, the via-wirings 304 may be disposed at the positions in the Y-direction corresponding to all the insulating members 105, similarly to the third embodiment.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a plurality of first wirings arranged in a first direction and extending in a second direction intersecting with the first direction;
a plurality of second wirings arranged in the first direction, extending in the second direction, and arranged with the plurality of first wirings in a third direction intersecting with the first direction and the second direction;
a first insulating member and a second insulating member disposed between the plurality of first wirings and the plurality of second wirings, arranged in the second direction, and extending in the first direction and the third direction;
a plurality of first semiconductor layers disposed between the first insulating member and the second insulating member, arranged in the first direction, and extending in the third direction;
a plurality of first gate electrodes arranged in the first direction, electrically connected to the respective plurality of first wirings, and opposed to the plurality of first semiconductor layers;
a first via-wiring extending in the first direction and electrically connected to the plurality of first semiconductor layers;
a plurality of second semiconductor layers disposed between the first insulating member and the second insulating member, arranged in the first direction, and extending in the third direction;
a plurality of second gate electrodes arranged in the first direction, electrically connected to the respective plurality of second wirings, and opposed to the plurality of second semiconductor layers;
a second via-wiring extending in the first direction and electrically connected to the plurality of second semiconductor layers;
a plurality of third semiconductor layers disposed between the plurality of first semiconductor layers and the plurality of second semiconductor layers, arranged in the first direction, and extending in the third direction, the plurality of third semiconductor layers being electrically connected to the respective plurality of second semiconductor layers;
a plurality of third gate electrodes arranged in the first direction, electrically connected to the respective plurality of first semiconductor layers, and opposed to the plurality of third semiconductor layers; and
a third via-wiring extending in the first direction and electrically connected to the plurality of third semiconductor layers, wherein
on a predetermined cross-sectional surface extending in the second direction and the third direction,
an end portion of the third via-wiring on one side in the second direction is disposed between a first position in the second direction corresponding to a side surface of the first insulating member on a second insulating member side and a second position in the second direction corresponding to a side surface of the second insulating member on a first insulating member side, and
an end portion of the third via-wiring on the other side in the second direction is not disposed between the first position and the second position.

2. The semiconductor memory device according to claim 1, wherein
on the predetermined cross-sectional surface, a side surface of one of the plurality of third gate electrodes on one side in the second direction includes a curved part formed along a part of an outer peripheral surface of the third via-wiring.

3. The semiconductor memory device according to claim 2, wherein
on the predetermined cross-sectional surface, a side surface of the one of the plurality of third gate electrodes on the other side in the second direction includes a linear part formed along the second insulating member.

4. The semiconductor memory device according to claim 1, wherein
on the predetermined cross-sectional surface, a side surface of the first insulating member on the second insulating member side includes:
a linear first part disposed at the first position and extending in the third direction; and
a curved second part continuous with the first part and formed along a part of an outer peripheral surface of the third via-wiring.

5. The semiconductor memory device according to claim 4, wherein
on the predetermined cross-sectional surface, a side surface of the second insulating member on the first insulating member side includes a linear third part disposed at the second position and extending in the third direction.

6. The semiconductor memory device according to claim 1, wherein
on the predetermined cross-sectional surface,
an end portion of the first via-wiring on one side in the second direction is disposed between the first position and the second position, and
an end portion of the first via-wiring on the other side in the second direction is not disposed between the first position and the second position.

7. The semiconductor memory device according to claim 6, wherein
on the predetermined cross-sectional surface, a side surface of the first insulating member or the second insulating member includes a curved part formed along a part of an outer peripheral surface of the first via-wiring.

8. The semiconductor memory device according to claim 1, wherein
on the predetermined cross-sectional surface,
an end portion of the second via-wiring on one side in the second direction is disposed between the first position and the second position, and
an end portion of the second via-wiring on the other side in the second direction is not disposed between the first position and the second position.

9. The semiconductor memory device according to claim 8, wherein
on the predetermined cross-sectional surface, a side surface of the first insulating member or the second insulating member includes a curved part formed along a part of an outer peripheral surface of the second via-wiring.

10. The semiconductor memory device according to claim 1, wherein
on the predetermined cross-sectional surface, the first insulating member is separated in the third direction via the third via-wiring.

11. The semiconductor memory device according to claim 1, comprising
a fourth via-wiring disposed on an opposite side of the third via-wiring with respect to the plurality of third semiconductor layers in the second direction, the fourth via-wiring extending in the first direction and electrically connected to the plurality of third semiconductor layers, wherein
on the predetermined cross-sectional surface,
an end portion of the fourth via-wiring on one side in the second direction is disposed between the first position and the second position, and
an end portion of the fourth via-wiring on the other side in the second direction is not disposed between the first position and the second position.

12. The semiconductor memory device according to claim 11, wherein
on the predetermined cross-sectional surface,
a side surface of one of the plurality of third gate electrodes on one side in the second direction includes a curved part formed along a part of an outer peripheral surface of the third via-wiring, and
a side surface of the one of the plurality of third gate electrodes on the other side in the second direction includes a curved part formed along another part of an outer peripheral surface of the fourth via-wiring.

13. The semiconductor memory device according to claim 1, wherein
the plurality of third semiconductor layers are opposed to surfaces of the respective plurality of third gate electrodes on one side and the other side in the first direction.

14. The semiconductor memory device according to claim 13, comprising
a plurality of fourth gate electrodes arranged in the first direction, electrically connected to the respective plurality of third gate electrodes, and opposed to the plurality of second semiconductor layers, wherein
the plurality of second semiconductor layers are opposed to surfaces of the respective plurality of fourth gate electrodes on one side and the other side in the first direction, and
the plurality of second gate electrodes are opposed to surfaces of the respective plurality of second semiconductor layers on one side and the other side in the first direction.

15. The semiconductor memory device according to claim 1, wherein
the plurality of third gate electrodes are opposed to surfaces of the respective plurality of third semiconductor layers on one side and the other side in the first direction.

16. The semiconductor memory device according to claim 15, comprising
a plurality of fifth gate electrodes arranged in the first direction, electrically connected to the respective plurality of third gate electrodes, and opposed to the plurality of second semiconductor layers, wherein
the plurality of fifth gate electrodes are opposed to surfaces of the respective plurality of second semiconductor layers on one side and the other side in the first direction, and
the plurality of second gate electrodes are opposed to surfaces of the respective plurality of fifth gate electrodes on one side and the other side in the first direction.
